(19) United States
(12) Patent Application Publication
(10) Pub. No.: US 2025/0066173 A1
(43) Pub. Date: Feb. 27, 2025

(54) ROTARY SENSOR MOUNT FOR LIFT DEVICE

(71) Applicant: Oshkosh Corporation, Oshkosh, WI (US)

(72) Inventors: Wenton Miller, Oshkosh, WI (US); Scott Riley, Oshkosh, WI (US); Daniel Yednock, Oshkosh, WI (US)

(21) Appl. No.: 18/813,340

(22) Filed: Aug. 23, 2024

Related U.S. Application Data
(60) Provisional application No. 63/534,434, filed on Aug. 24, 2023.

(51) Int. Cl. B66F 11/04; G01B 7/30

(52) U.S. Cl. CPC B66F 11/044; G01B 7/30

(57) ABSTRACT

A vehicle includes a base assembly and a lift assembly configured to raise or lower a platform coupled. The lift assembly includes an arm rotatable relative to the base assembly by a first pivot pin, and a rotary sensor. The rotary sensor monitors a rotation of one of the arm or the first pivot pin and includes a mounting cup configured to receive a portion of the first pivot pin, an indicator coupled to one of the portion of the first pivot pin or the mounting cup, an electronic sensor coupled to the other of the portion of the first pivot pin or the mounting cup and configured to monitor a rotation of the indicator, and a resilient member configured to exert at least one of an axial force or torsional force on the mounting cup.

### CROSS-REFERENCE TO RELATED PATENT APPLICATION

This application claims the benefit of and priority to U.S. Provisional Application No. 63/534,434, filed on Aug. 24, 2023, the entire disclosure of which is hereby incorporated by reference herein.

### BACKGROUND

The present disclosure relates to lift devices. More specifically, the present disclosure relates to a sensor mount for monitoring rotating joints in a lift device.

### SUMMARY

At least one embodiment relates to a lift device including a base assembly and a lift assembly coupled with the base assembly and configured to raise or lower a platform coupled with an end of the lift assembly. The lift assembly includes an arm supported by the base assembly and a first pivot comprising a first pivot pin, the arm rotatably relative to the base assembly by the first pivot. The lift assembly further includes a rotary sensor supported by the base assembly, the rotary sensor configured to monitor a rotation of one of the arm or the first pivot pin about an axis. The rotary sensor includes a mounting cup configured to receive at least a portion of the first pivot pin, wherein the first pivot pin is rotatable relative to the mounting cup; an indicator coupled to one of the portion of the first pivot pin or the mounting cup, an electronic sensor coupled to the other of the portion of the first pivot pin or the mounting cup, the electronic sensor configured to monitor a rotation of the indicator, and a resilient member configured to exert at least one of an axial force or torsional force on the mounting cup along the axis.

Another embodiment relates to a rotary sensor for a work machine including a mounting cup configured to receive at least a portion of a pin configured to rotate relative to the mounting cup about an axis, an indicator coupled to one of the mounting cup or the pin, an electronic sensor coupled to the other of the mounting cup or the pin, the electronic sensor configured to monitor a rotation of the indicator, a resilient member configured to exert at least one of an axial force or torsional force on the mounting cup along the axis, and a fixed rod extending partially within the mounting cup, wherein the fixed rod prevents the mounting cup from rotating 360 degrees.

Another embodiment relates to A pin joint for a work machine including a first member including a fork with a first side and a second side, wherein the first side and the second side have concentric fork apertures, a second member including an eye, wherein the eye is concentric with the fork apertures, and a pin extending through the fork apertures and the eye to rotatably couple to the first member and the second member. The pin is fixedly coupled to the second member via a bolt passing through the second member and the pin orthogonal to a rotational axis of the pin, wherein the bolt is retained by a cone-shaped bushing, and the bolt passes through the threaded aperture of the second member, a threaded center of the bushing, the pin, and a second aperture of the second member to secure the pin to the second member.

### BRIEF DESCRIPTION OF THE DRAWINGS

FIG. 1 is a perspective view of a lift device, according to an embodiment.

FIG. 2 is a perspective view of a base of the lift device of FIG. 1.

FIG. 3 is a perspective view of an axle assembly of the lift device of FIG. 1.

FIG. 4 is a perspective view of a platform assembly of the lift device of FIG. 1.

FIG. 5 is a right side of the lift device of FIG. 1 including a modular turntable hood.

FIG. 6 is a perspective view of a pivot point of the lift device of FIG. 5 including a rotary sensor mount.

FIG. 7 is a perspective view of an interior of the rotary sensor mount of FIG. 6 . . .

FIG. 8 is another perspective view of an interior of the rotary sensor mount of FIG. 6.

FIG. 9 is a perspective view of a rotary sensor mount for the lift device of FIG. 1, according to another embodiment.

FIG. 10 is a perspective view of a mounting cup of the rotary sensor mount of FIG. 6 . . . .

FIG. 11 is a perspective view of a pin of a rotary sensor mount of FIG. 6.

FIG. 12 is a section view of the rotary sensor mount of FIG. 6.

FIG. 13 is perspective view of a pivot point of a lift device with a bolt assembly.

FIG. 14 is a section view of the pivot point and bolt assembly of FIG. 13, according to some embodiments.

FIG. 15 is cross-section view of the bolt assembly of FIG. 13.

FIG. 16 is a perspective view of a rotary sensor mount for the lift device of FIG. 1, according to another embodiment.

FIG. 17 is a top view of the rotary sensor mount of FIG. 16.

FIG. 18 is a bottom view of the rotary sensor mount of FIG. 16.

FIG. 19 is a front view of the rotary sensor mount of FIG. 16.

FIG. 20 is a perspective of a cross-section view of the rotary sensor mount of FIG. 19.

FIG. 21 is a top view of the cross-section view of FIG. 20.

FIG. 22 is a section view of the rotary sensor mount of FIG. 17.

FIG. 23 is a section view of the rotary sensor mount of FIG. 18.

FIG. 24 is a side view of the rotary sensor mount of FIG. 16.

FIG. 25 is a perspective view of a pivot point of the lift device of FIG. 5 including a rotary sensor mount, according to another embodiment.

FIG. 26 is a section view of the rotary sensor mount of FIG. 25.

FIG. 27 is a perspective view of a rotary sensor mount for the lift device of FIG. 1, according to another embodiment.

FIG. 28 is a section view of the rotary sensor mount of FIG. 27.

FIG. 29 is a perspective view of a rotary sensor mount for the lift device of FIG. 1, according to another embodiment.

FIG. 30 is a section view of the rotary sensor mount of FIG. 29.

FIG. 31 is a perspective view of a rotary sensor mount for the lift device of FIG. 1, according to another embodiment.

FIG. 32 is a perspective view of a rotary sensor mount for the lift device of FIG. 1, according to another embodiment.

FIG. 33 is a section view of a rotary sensor mount for the lift device of FIG. 1, according to another embodiment.

### DETAILED DESCRIPTION

Before turning to the figures, which illustrate the exemplary embodiments in detail, it should be understood that the present disclosure is not limited to the details or methodology set forth in the description or illustrated in the figures. It should also be understood that the terminology used herein is for the purpose of description only and should not be regarded as limiting.

### Overview

Referring generally to the FIGURES, a rotary sensor mount is shown according to various exemplary embodiments. Some lift devices include a platform with a position controlled by one or more rotatable joints of a lift assembly. The position of the platform is derived from measuring the rotation of the one or more rotatable joints. Some lift devices measure the rotation with protractor angle sensors susceptible to large angle errors based on mounting misalignment between the sensor and the sensed rotating member.

The rotary sensor mount according to various exemplary embodiments described herein improves such systems by providing a mount for a non-contact rotary angle sensor. The mount includes one or more force members (e.g., springs, actuators, etc.) connected to the mount to preload the mount and maintain the axial and radial position of the mount relative to the axis. A first force member parallel to the axis exerts an axial force to engage radial surfaces of the mount with radial surfaces of the rotating member along the rotating axis to maintain the axial position of the mount. A second force member perpendicular to the axis exerts a rotating force on the mount in a first direction, while a braking member (pin, rod, stop, etc.) exerts a counteracting rotating force on the mount to resist the rotating force and maintain the rotational position of the mount. Lateral surfaces of the mount engage with lateral surfaces of the rotating member to keep the sensor concentric with the axis.

As the rotating member rotates, the abutting radial and lateral surfaces of the rotating member rotate relative to the mount. The first force member exerts the axial force to keep the mount in contact with the rotating member. The mount remains substantially fixed relative to the rotating member due to the rotational force from the second force member acting to preload the mount and substantially prevent the mount from rotating with the rotating member due to friction.

In some lift devices the rotatable joints are pin joints with a fork and an eye or bushing rotatable coupled to each other by a pin. Some such lift devices may fix the pin to the eye and measure a rotation of the pin as a proxy for the rotation of the eye, however rotational backlash in the connection between the pin and the eye can interfere with an accurate measurement with precision.

The rotary sensor mount according to various exemplary embodiments described herein improves such systems by providing a tapered cone that threads into a corresponding threaded aperture in the eye and extending into a corresponding tapered countersink in the pin. A bolt passes through the eye, the tapered cone, and the pin to fix the pin to the eye. The inner diameter of the tapered cone is threaded to retain the bolt. The tapered cone prevents relative motion between the eye and the pin.

### Lift Device

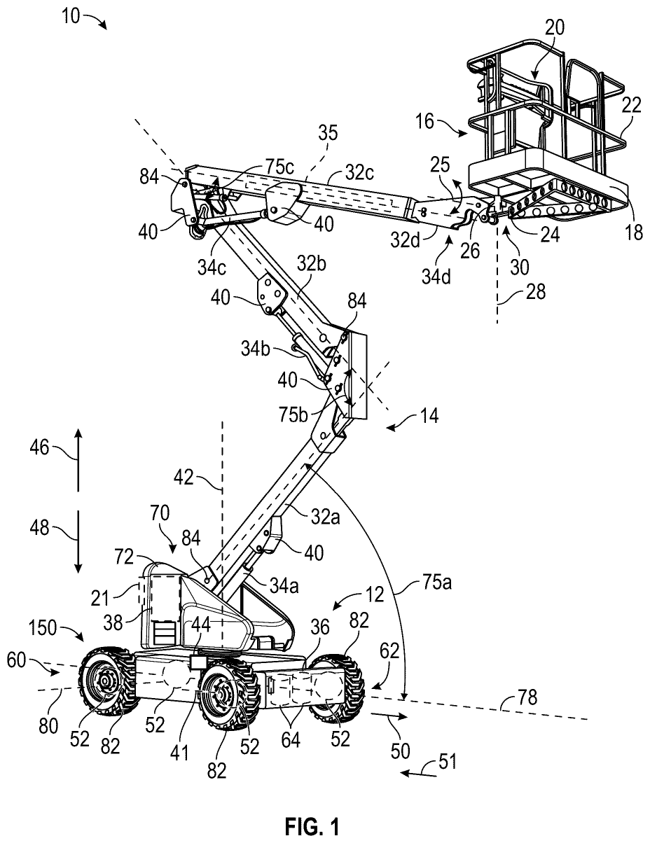

Referring to FIG. 1, a lifting apparatus, lift device, or mobile elevating work platform (MEWP) (e.g., a telehandler, an electric boom lift, a towable boom lift, a lift device, a fully electric boom lift, etc.), shown as lift device 10 includes a base assembly 12 (e.g., a base, a support assembly, a drivable support assembly, a support structure, a chassis, etc.), a the platform assembly 16 (e.g., a platform, a terrace, etc.), and a lift assembly 14 (e.g., a boom, a boom lift assembly, a lifting apparatus, an articulated arm, a scissors lift, etc.). The lift device 10 includes a front end (e.g., a forward facing end, a front portion, a front, etc.), shown as front 62, and a rear end (e.g., a rearward facing end, a back portion, a back, a rear, etc.,) shown as rear 60. The lift assembly 14 is configured to elevate the platform assembly 16 in an upwards direction 46 (e.g., an upward vertical direction) relative to the base assembly 12. The lift assembly 14 is also configured to translate the platform assembly 16 in a downwards direction 48 (e.g., a downward vertical direction). The lift assembly 14 is also configured to translate the platform assembly 16 in either a forwards direction 50 (e.g., a forward longitudinal direction) or a rearwards direction 51 (e.g., a rearward longitudinal direction). The lift assembly 14 generally facilitates performing a lifting function to raise and lower the platform assembly 16, as well as movement of the platform assembly 16 in various directions.

The base assembly 12 defines a longitudinal axis 78 and a lateral axis 80. The longitudinal axis 78 defines the forward direction 50 of lift device 10 and the rearward direction 51. The lift device 10 is configured to translate in the forward direction 50 and to translate backwards in the rearward direction 51. The base assembly 12 includes one or more wheels, tires, wheel assemblies, tractive elements, rotary elements, treads, etc., shown as tractive elements 82. The tractive elements 82 are configured to rotate to drive (e.g., propel, translate, steer, move, etc.) the lift device 10. The tractive elements 82 can each include an electric motor 52 (e.g., electric wheel motors) configured to drive the tractive elements 82 (e.g., to rotate tractive elements 82 to facilitation motion of the lift device 10). In other embodiments, the tractive elements 82 are configured to receive power (e.g., rotational mechanical energy) from electric motors 52 or through a drive train (e.g., a combination of any number and configuration of a shaft, an axle, a gear reduction, a gear train, a transmission, etc.). In some embodiments, one or more tractive elements 82 are driven by a prime mover 41 (e.g., electric motor, internal combustion engine, etc.) through a transmission. In some embodiments, a hydraulic system (e.g., one or more pumps, hydraulic motors, conduits, valves, etc.) transfer power (e.g., mechanical energy) from one or more electric motors 52 and/or the prime mover 41 to the tractive elements 82. The tractive elements 82 and electric motors 52 (or prime mover 41) can facilitate a driving and/or steering function of the lift device 10. In some embodiments, the electric motors 52 are optional, and the tractive elements 82 are powered or driven by an internal combustion engine.

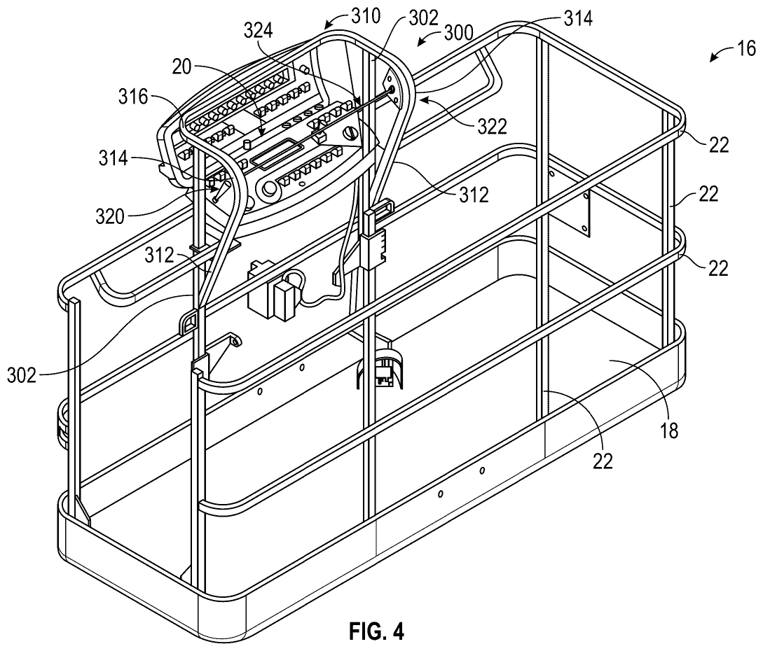

With additional reference to FIG. 4, the platform assembly 16 is shown in further detail. The platform assembly 16 is configured to provide a work area for an operator of the lift device 10 to stand/rest upon. The platform assembly 16 can be pivotally coupled to an upper end of the lift assembly 14. The lift device 10 is configured to facilitate the operator accessing various elevated areas (e.g., lights, platforms, the sides of buildings, building scaffolding, trees, power lines, etc.). The lift device 10 may use various electrically-powered motors and electrically-powered linear actuators or hydraulic cylinders to facilitate elevation and/or horizontal movement (e.g., lateral movement, longitudinal movement) of the platform assembly 16 (e.g., relative to the base assembly 12, or to a ground surface that the base assembly 12 rests upon). In some embodiments, the lift device 10 uses internal combustion engines, hydraulics, a hydraulic system, pneumatic cylinders, etc.

The platform assembly 16 includes a base member, a base portion, a platform, a standing surface, a shelf, a work platform, a floor, a deck, etc., shown as a deck 18. The deck 18 provides a space (e.g., a floor surface) for a worker to stand upon as the platform assembly 16 is raised and lowered.

The platform assembly 16 includes a railing assembly including various members, beams, bars, guard rails, rails, railings, etc., shown as rails 22. The rails 22 extend along substantially an entire perimeter of the deck 18. The rails 22 provide one or more members for the operator of the lift device 10 to grasp while using the lift device 10 (e.g., to grasp while operating the lift device 10 to elevate the platform assembly 16). The rails 22 can include members that are substantially horizontal to the deck 18. The rails 22 can also include vertical structural members that couple with the substantially horizontal members. The vertical structural members can extend upwards from the deck 18.

The platform assembly 16 can include a human machine interface (HMI) (e.g., a user interface, an operator interface, etc.), shown as the user interface 20. The user interface 20 is configured to receive user inputs from the operator at or upon the platform assembly 16 to facilitate operation of the lift device 10. The user interface 20 can include any number of buttons, levers, switches, keys, etc., or any other user input device configured to receive a user input to operate the lift device 10. The user interface 20 may also provide information to the user (e.g., through one or more displays, lights, speakers, haptic feedback devices, etc.). The user interface 20 can be supported by one or more of the rails 22.

Referring to FIG. 1, the platform assembly 16 includes a frame 24 (e.g., structural members, support beams, a body, a structure, etc.) that extends at least partially below the deck 18. The frame 24 can be integrally formed with the deck 18. The frame 24 is configured to provide structural support for the deck 18 of the platform assembly 16. The frame 24 can include any number of structural members (e.g., beams, bars, I-beams, etc.) to support the deck 18. The frame 24 couples the platform assembly 16 with the lift assembly 14. The frame 24 may be rotatably or pivotally coupled with the lift assembly 14 to facilitate rotation of the platform assembly 16 about an axis 28 (e.g., a vertical axis). The frame 24 can also rotatably/pivotally couple with the lift assembly 14 such that the frame 24 and the platform assembly 16 can pivot about an axis 25 (e.g., a horizontal axis).

The lift assembly 14 includes one or more beams, articulated arms, bars, booms, arms, support members, boom sections, cantilever beams, etc., shown as lift arms 32a, 32b, and 32c. The lift arms are hingedly or rotatably coupled with each other at their ends. The lift arms can be hingedly or rotatably coupled to facilitate articulation of the lift assembly 14 and raising/lowering and/or horizontal movement of the platform assembly 16. The lift device 10 includes a lower lift arm 32a, a central or medial lift arm 32b, and an upper lift arm 32c. The lower lift arm 32a is configured to hingedly or rotatably couple at one end with the base assembly 12 to facilitate lifting (e.g., elevation) of the platform assembly 16. The lower lift arm 32a is configured to hingedly or rotatably couple at an opposite end with the medial lift arm 32b. Likewise, the medial lift arm 32b is configured to hingedly or rotatably couple with the upper lift arm 32c. The upper lift arm 32c can be configured to hingedly interface/couple and/or telescope with an intermediate lift arm 32d. The upper lift arm 32c can be referred to as “the jib” of the lift device 10. The intermediate lift arm 32d may extend into an inner volume of the upper lift arm 32c and extend and/or retract. The lower lift arm 32a and the medial lift arm 32b may be referred to as “the boom” of the overall lift device 10 assembly. The intermediate lift arm 32d can be configured to couple (e.g., rotatably, hingedly, etc.), with the platform assembly 16 to facilitate levelling of the platform assembly 16.

The lift arms 32 are driven to hinge or rotate relative to each other by actuators 34a, 34b, 34c, and 34d (e.g., electric linear actuators, linear electric arm actuators, hydraulic cylinders, etc.). The actuators 34a, 34b, 34c, and 34d can be mounted between adjacent lift arms to drive adjacent lift arms to hinge or pivot (e.g., rotate some angular amount) relative to each other about pivot points 84. The actuators 34a, 34b, 34c, and 34d can be mounted between adjacent lift arms using any of a foot bracket, a flange bracket, a clevis bracket, a trunnion bracket, etc. The actuators 34a, 34b, 34c, and 34d may be configured to extend or retract (e.g., increase in overall length, or decrease in overall length) to facilitate pivoting adjacent lift arms to pivot/hinge relative to each other, thereby articulating the lift arms and raising or lowering the platform assembly 16.

The actuators 34a, 34b, 34c, and 34d can be configured to extend (e.g., increase in length) to increase a value of an angle formed between adjacent lift arms 32. The angle can be defined between centerlines of adjacent lift arms 32 (e.g., centerlines that extend substantially through a center of the lift arms 32). For example, the actuator 34a is configured to extend/retract to increase/decrease the angle 75a defined between a centerline of the lower lift arm 32a and the longitudinal axis 78 (angle 75a can also be defined between the centerline of the lower lift arm 32a and a plane defined by the longitudinal axis 78 and lateral axis 80) and facilitate lifting of the platform assembly 16 (e.g., moving the platform assembly 16 at least partially along the upward direction 46). Likewise, the actuator 34b can be configured to retract to decrease the angle 75a to facilitate lowering of the platform assembly 16 (e.g., moving the platform assembly 16 at least partially along the downward direction 48). Similarly, the actuator 34b is configured to extend to increase the angle 74b defined between centerlines of the lower lift arm 32a and the medial lift arm 32b and facilitate elevating of the platform assembly 16. Similarly, the actuator 34b is configured to retract to decrease the angle 74b to facilitate lowering of the platform assembly 16. The electric actuator 34c is similarly configured to extend/retract to increase/decrease the angle 74c, respectively, to raise/lower the platform assembly 16. The actuators 34 may be hydraulic actuators, electric actuators, pneumatic actuators, etc.

The actuators 34a, 34b, 34c, and 34d can be mounted (e.g., rotatably coupled, pivotally coupled, etc.) to adjacent lift arms at mounts 40 (e.g., mounting members, mounting portions, attachment members, attachment portions, etc.). The mounts 40 can be positioned at any position along a length of each lift arm. For example, the mounts 40 can be positioned at a midpoint of each lift arm, and a lower end of each lift arm.

The intermediate lift arm 32d and the frame 24 are configured to pivotally interface/couple at a platform rotator 30 (e.g., a rotary actuator, a rotational electric actuator, a gear box, etc.). The platform rotator 30 facilitates rotation of the platform assembly 16 about the axis 28 relative to the intermediate lift arm 32d. In some embodiments, the platform rotator 30 is positioned between the frame 24 and the upper lift arm 32c and facilitates pivoting of the platform assembly 16 relative to the upper lift arm 32c. The axis 28 extends through a central pivot point of the platform rotator 30. The intermediate lift arm 32d can also be configured to articulate or bend such that a distal portion of the intermediate lift arm 32d pivots/rotates about the axis 25. The intermediate lift arm 32d can be driven to rotate/pivot about axis 25 by extension and retraction of the actuator 34d.

The intermediate lift arm 32d is also configured to extend/retract (e.g., telescope) along the upper lift arm 32c. In some embodiments, the lift assembly 14 includes a linear actuator (e.g., a hydraulic cylinder, an electric linear actuator, etc.), shown as extension actuator 35, that controls extension and retraction of the intermediate lift arm 32d relative to the upper lift arm 32c. In other embodiments, one more of the other arms of the lift assembly 14 include multiple telescoping sections that are configured to extend/retract relative to one another.

The platform assembly 16 is configured to be driven to pivot about the axis 28 (e.g., rotate about axis 28 in either a clockwise or a counter-clockwise direction) by an electric or hydraulic motor 26 (e.g., a rotary electric actuator, a stepper motor, a platform rotator, a platform electric motor, an electric platform rotator motor, etc.). The motor 26 can be configured to drive the frame 24 to pivot about the axis 28 relative to the upper lift arm 32c (or relative to the intermediate lift arm 32d). The motor 26 can be configured to drive a gear train to pivot the platform assembly 16 about the axis 28.

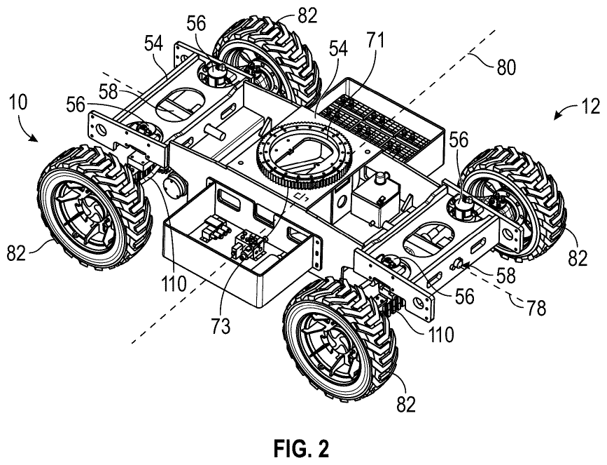

Referring to FIGS. 1 and 2, the lift assembly 14 is configured to pivotally or rotatably couple with the base assembly 12. The base assembly 12 includes a rotatable base member, a rotatable platform member, a fully electric turntable, etc., shown as a turntable 70. The lift assembly 14 is configured to rotatably/pivotally couple with the base assembly 12. The turntable 70 is rotatably coupled with a base, frame, structural support member, carriage, etc., of base assembly 12, shown as base 36. The turntable 70 is configured to rotate or pivot relative to the base 36. The turntable 70 can pivot/rotate about the central axis 42 relative to base 36, about a slew bearing 71 (e.g., the slew bearing 71 pivotally couples the turntable 70 to the base 36). The turntable 70 facilitates accessing various elevated and angularly offset locations at the platform assembly 16. The turntable 70 is configured to be driven to rotate or pivot relative to base 36 and about the slew bearing 71 by an electric motor, an electric turntable motor, an electric rotary actuator, a hydraulic motor, etc., shown as the turntable motor 44. The turntable motor 44 can be configured to drive a geared outer surface 73 of the slew bearing 71 that is rotatably coupled to the base 36 about the slew bearing 71 to rotate the turntable 70 relative to the base 36. The lower lift arm 32a is pivotally coupled with the turntable 70 (or with a turntable member 72 of the turntable 70) such that the lift assembly 14 and the platform assembly 16 rotate as the turntable 70 rotates about the central axis 42. In some embodiments, the turntable 70 is configured to rotate a complete 360 degrees about the central axis 42 relative to the base 36. In other embodiments, the turntable 70 is configured to rotate an angular amount less than 360 degrees about the central axis 42 relative to the base 36 (e.g., 270 degrees, 120 degrees, etc.).

The base assembly 12 includes one or more energy storage devices or power sources (e.g., capacitors, batteries, Lithium-Ion batteries, Nickel Cadmium batteries, fuel tanks, etc.), shown as batteries 64. The batteries 64 are configured to store energy in a form (e.g., in the form of chemical energy) that can be converted into electrical energy for the various electric motors and actuators of the lift device 10. The batteries 64 can be stored within the base 36. The lift device 10 includes a controller 38 that is configured to operate any of the motors, actuators, etc., of the lift device 10. The controller 38 can be configured to receive sensory input information from various sensors of the lift device 10, user inputs from the user interface 20 (or any other user input device such as a key-start or a push-button start), etc. The controller 38 can be configured to generate control signals for the various motors, actuators, etc., of the lift device 10 to operate any of the motors, actuators, electrically powered movers, etc., of the lift device 10. The batteries 64 are configured to power any of the motors, sensors, actuators, electric linear actuators, electrical devices, electrical movers, stepper motors, etc., of the lift device 10. The base assembly 12 can include a power circuit including any necessary transformers, resistors, transistors, thermistors, capacitors, etc., to provide appropriate power (e.g., electrical energy with appropriate current and/or appropriate voltage) to any of the motors, electric actuators, sensors, electrical devices, etc., of the lift device 10.

The batteries 64 are configured to deliver power to the motors 52 to drive the tractive elements 82. A rear set of tractive elements 82 can be configured to pivot to steer the lift device 10. In other embodiments, a front set of tractive elements 82 are configured to pivot to steer the lift device 10. In still other embodiments, both the front and the rear set of tractive elements 82 are configured to pivot (e.g., independently) to steer the lift device 10. In some examples, the base assembly 12 includes a steering system 150. The steering system 150 is configured to drive tractive elements 82 to pivot for a turn of the lift device 10. The steering system 150 can be configured to pivot the tractive elements 82 in pairs (e.g., to pivot a front pair of tractive elements 82), or can be configured to pivot tractive elements 82 independently (e.g., four-wheel steering for tight-turns).

It should be understood that while the lift device 10 as described herein is described with reference to batteries, electric motors, etc., the lift device 10 can be powered (e.g., for transportation and/or lifting the platform assembly 16) using one or more internal combustion engines, electric motors or actuators, hydraulic motors or actuators, pneumatic actuators, or any combination thereof.

In some embodiments, the base assembly 12 also includes a user interface 21 (e.g., a HMI, a user interface, a user input device, a display screen, etc.). In some embodiments, the user interface 21 is coupled to the base 36. In other embodiments, the user interface 21 is positioned on the turntable 70. The user interface 21 can be positioned on any side or surface of the base assembly 12 (e.g., on the front 62 of the base 36, on the rear 60 of the base 36, etc.).

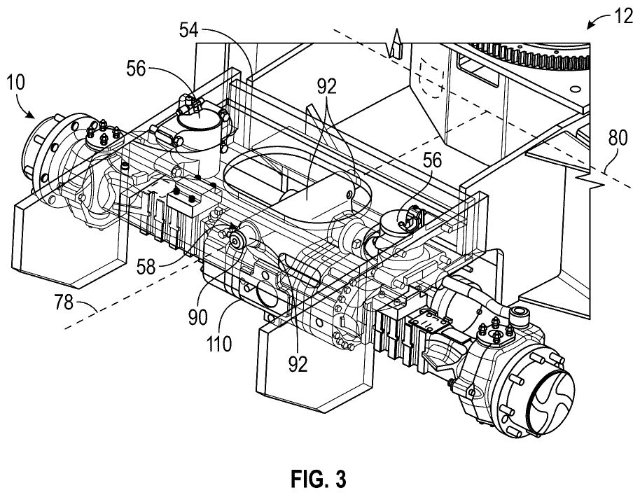

Referring now to FIGS. 2 and 3, the base assembly 12 includes a longitudinally extending frame member 54 (e.g., a rigid member, a structural support member, an axle, a base, a frame, a carriage, a chassis, etc.). The longitudinally extending frame member 54 provides structural support for the turntable 70 as well as the tractive elements 82. The longitudinally extending frame member 54 is pivotally coupled with lateral frame members 110 (e.g., axles, frame members, beams, bars, etc.) at opposite longitudinal ends of the longitudinally extending frame member 54. For example, the lateral frame members 110 may be pivotally coupled with the longitudinally extending frame member 54 at a front end and a rear end of the longitudinally extending frame member 54. The lateral frame members 110 can each be configured to pivot about a pivot joint 58 (e.g., about a longitudinal axis). The pivot joint 58 can include a pin and a receiving portion (e.g., a bore, an aperture, etc.). The pin of the pivot joint 58 is coupled to one of the lateral frame members 110 (e.g., a front lateral frame member 110 or a rear lateral frame member 110) or the longitudinally extending frame member 54 and the receiving portion is coupled to the other of the longitudinally extending frame member 54 and the lateral frame member 110. For example, the pin may be coupled with longitudinally extending frame member 54 and the receiving portion can be coupled with one of the lateral frame members 110 (e.g., integrally formed with the front lateral frame member 110).

In some embodiments, the longitudinally extending frame member 54 and the lateral frame members 110 are integrally formed or coupled (e.g., fastened, welded, riveted, etc.) to define the base 36. In still other embodiments, the base 36 is integrally formed with the longitudinally extending frame member 54 and/or the lateral frame members 110. In still other embodiments, the base 36 is coupled with the longitudinally extending frame member 54 and/or the lateral frame members 110.

The base assembly 12 includes one or more axle actuators 56 (e.g., electric linear actuators, electric axle actuators, electric levelling actuators, hydraulic cylinders, etc.). The axle actuators 56 can be linear actuators configured to receive power from the batteries 64, for example. The axle actuators 56 can be configured to extend or retract to contact a top surface of a corresponding one of the lateral frame members 110. When the axle actuators 56 extend, an end of a rod of the levelling actuators can contact the surface of lateral frame member 110 and prevent relative rotation between lateral frame member 110 and longitudinally extending frame member 54. In this way, the relative rotation/pivoting between the lateral frame member 110 and the longitudinally extending frame member 54 can be locked (e.g., to prevent rolling of the longitudinally extending frame member 54 relative to the lateral frame members 110 during operation of the lift assembly 14). The axle actuators 56 can receive power from the batteries 64, which can allow the axle actuators 56 to extend or retract. The axle actuators 56 receive control signals from controller 38.

### Rotary Sensor Mount

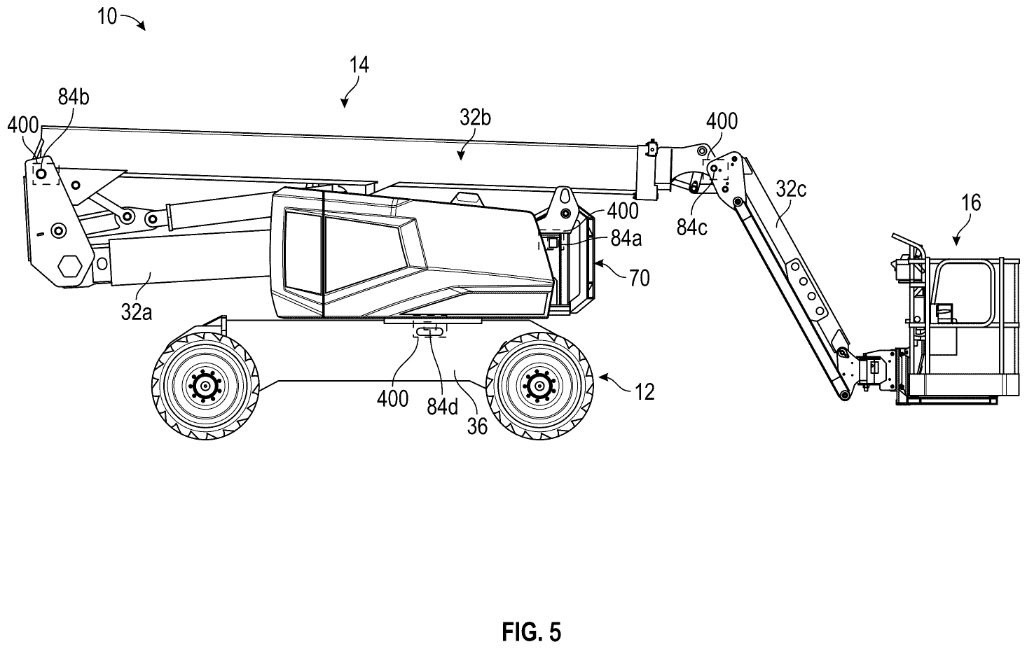

Referring to FIG. 5, a side view of the lift device 10 is shown according to an exemplary embodiment. The lift device 10 includes a base assembly 12 including a base 36, and a turntable 70 rotatably coupled to the base 36 about pivot point 84d. A lift assembly 14 is coupled to the turntable 70 and configured to position the platform 16. The lift assembly 14 includes lift arms 32a, 32b, and 32c which are rotated by one or more actuators (e.g., actuators 34a, 34b, 34c, and 34d) relative to each other and the base assembly 12 about the pivot points 84a-84c. The lift device 10 includes one or more rotary angle sensors shown as sensors 400 configured to measure a rotation of one of the lift arms 32a, 32b, or 32c, or the turntable 70, respectively. In some embodiments, the sensor 400 is configured to measure a rotation of the lift arm 32a relative to the turntable 70 or a tower arm of the turntable 70. In some embodiments, the sensor 400 is configured to measure a rotation of the lift arm 32b relative to the lift arm 32a. In some embodiments, the sensor 400 is configured to measure a rotation of the lift arm 32c relative to the lift arm 32b. In some embodiments, the sensor 400 is configured to measure the rotation of the turntable 70 relative to the base 36. The sensor 400 can be used at any rotatable joint or coupling of the lift device 10. For example, the sensor 400 can measure the rotation at any rotating pin-joint in the lift device 10, and in some embodiments multiple sensors 400 may be used to measure multiple pivot points and rotatable joints or couplings.

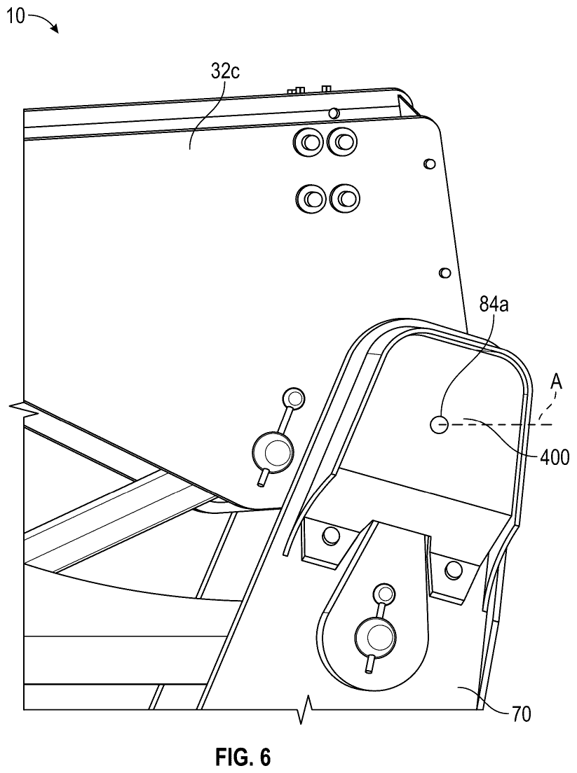

Referring to FIG. 6, a perspective view of a pivot point 84 is shown, according to an exemplary embodiment. A portion of the turntable 70 shown as a tower boom is rotatably coupled to the lift arm 32a a rotatable axis shown as axis A. A sensor 400 is positioned axially on axis A to measure the rotation of the lift arm 32a relative to the turntable 70. The sensor 400 may be mounted on either rotatable segment of a joint. For example, referring still to FIG. 6, the sensor 400 can be mounted to the tower arm of turntable 70 or to the lift arm 32c.

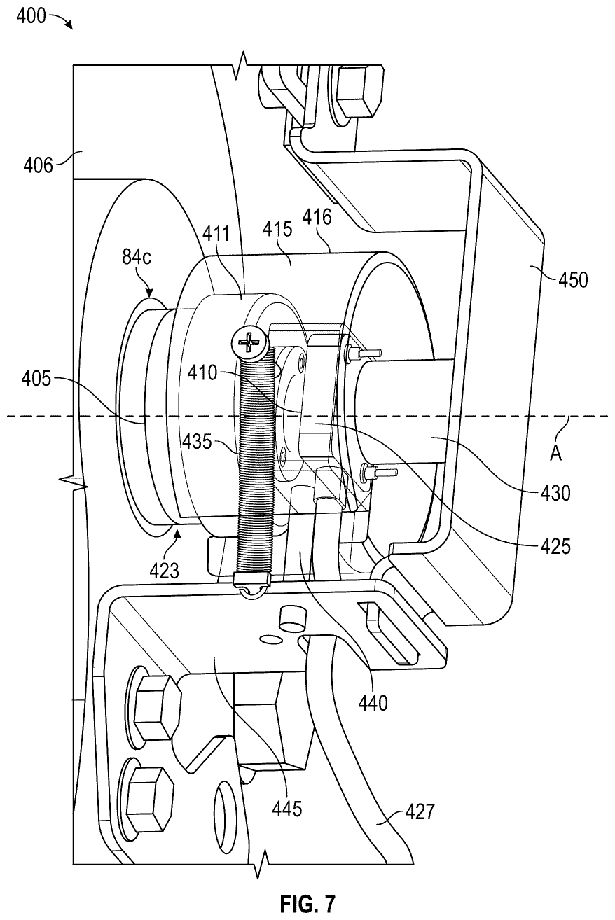

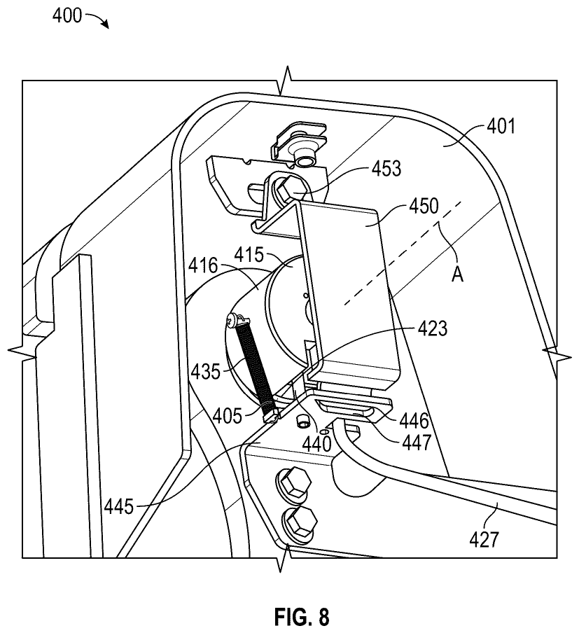

Referring now to FIGS. 7 and 8, a perspective view of an interior of the sensor 400 is shown, according to an exemplary embodiment. Pivot point 84a includes a rotating member (e.g., pin, rod, axle, shaft, etc.) shown as pin 405 that rotates around the axis A. The pin 405 extends into a housing 401 of the sensor 400. The pin 405 is fixedly coupled to the rotating element being tracked (e.g. lift arm 32a-32c) such that the rotation of the rotating element corresponds with the rotation of the pin 405 about the axis A. Coupled to the pin 405 is a tracked element (e.g., magnet, visual marker, etc.) shown as sensor magnet 410. Sensor magnet 410 can be a sensor magnet 410 for a Hall effect sensor. In some embodiments, the sensor magnet 410 is coupled to the pin 405 via an adapter, shown as adaptor 411. The adaptor 411 may be fixedly coupled to the pin 405 such that the adaptor 411 rotates with the pin 405 and fixedly coupled to the sensor magnet 410 such that the rotation of the sensor magnet 410 corresponds to the rotation of the pin 405. Beneficially, the adaptor 411 can couple to pins of various sizes while standardizing the mounting surface for the sensor magnet 410. In some embodiments, this lets the sensor 400 be installed on a variety of pin-joints. In other embodiments, the sensor magnet 410 may be directly coupled to the end of the pin 405.

Referring still to FIGS. 7 and 8, a sensor mount, shown as mounting cup 415, receives the end of the pin 405 including the sensor magnet 410 and the adaptor 411, if present. The mounting cup 415 receives the end of the pin 405 while still letting the pin 405 rotate relative to the mounting cup 415. The mounting cup 415 is positioned axially along the axis A and rotate independent of the pin 405. The mounting cup 415 is circular. In some embodiments, the mounting cup 415 is another shape and may have one or more planar sides.

A sensor (e.g., Hall effect sensor, camera, etc.) shown as magnetic sensor 425 is supported within the mounting cup. The magnetic sensor 425 is positioned axially along the axis A colinearly with the pin 405 and the sensor magnet 410. The magnetic sensor 425 may be coupled to the mounting cup 415 using one or more screws, fasteners, clips, adhesives, etc. The mounting cup 415 positions the magnetic sensor 425 both axially and radially relative to the sensor magnet 410. Rotary sensors can suffer from large angle errors based on several factors such as an improper axial distance or airgap between the sensed element (i.e., the sensor magnet 410) and the sensor (i.e., the magnetic sensor 425), an angular misalignment between a plane of the sensed element and the sensor, or a radial misalignment between the axis of sensed element and the sensor. The mounting cup 415 receives the end of the first pin 405 ensuring the axes of the sensor magnet 410 and the magnetic sensor 425 are aligned, while the magnetic sensor 425 mounting position within the mounting cup 415 ensures the planes of the sensor magnet 410 and the magnetic sensor 425, as well as the axial distance between them, are fixed. A wire, shown as wire 427 electrically coupling the magnetic sensor 425 to the lift device 10 exits the mounting cup 415 via the a gap 423 in a rim of the mounting cup 415.

While shown with the sensor magnet 410 coupled to the pin 405 to rotate relative to the magnetic sensor 425, in some embodiments the magnetic sensor 425 is coupled to the pin 405 to rotate relative to the sensor magnet 410.

Referring still to FIGS. 7 and 8, a force exerting member (e.g., a resilient member, an actuator, etc.) shown as first spring 430 is positioned between the mounting cup 415 and a bracket 450. When positioned between the mounting cup 415 and the bracket 450, the first spring 430 is compressed and exerts an axial force substantially parallel and colinear with the axis A to push the mounting cup 415 against the pin 405, or the adaptor 411 if present. The compression force provided by the first spring 430 helps to ensure the mounting cup 415 stays in contact with the pin 405 as the pin rotates. The compression force also makes sure the airgap between the sensor magnet 410 and the magnetic sensor 425 remains relatively constant. In some embodiments, additionally and/or alternatively to the first spring 430, a resilient member including an expandable foam is added to exert the axial force against the mounting cup 415 onto the pin 405.

A second force exerting member, shown as second spring 435 is coupled to an outer lateral surface of the mounting cup 415, shown as exterior 416. An opposing end of the second spring 435 is fixedly coupled to an anchor point such as the turntable 70, the sensor housing 401, or the bracket 450. The second spring 435 exerts a pulling force on the mounting cup 415 offset from the axis A by a moment arm equal to a radius of the mounting cup 415, such that the second spring 435 exerts a rotational force on the mounting cup 415 about the axis A. The rotational force exerted by the second spring 435 acts to counteract any rotation imparted to the mounting cup 415 by the pin 405 or the adaptor 411. Due to the first spring 430 applying a compression force to seat the mounting cup 415 on the pin 405 or the adaptor 411, friction between the rotating pin 405 and the mounting cup 415 may impart a small rotational force on the mounting cup 415. The force exerted by the second spring 435 resists the rotational force due to the pin 405 by pre-loading or biasing the mounting cup 415. In some embodiments, the compressive force and the rotational force are provided by more or fewer force exerting members. For example, in some embodiments the first spring 430 is an open-wound torsion spring which can provide both the compressive force between the mounting cup 415 and the bracket 450 as well as the rotational force to resist the rotational forces acting on the mounting cup 415, and the second spring 435 may not be included.

To prevent rotation of the mounting cup 415 based on the pre-loading of the second spring 435, a fixed, non-rotatable member (e.g., pin, rod, plate, etc.) shown as rod 440 extends at least partially into the mounting cup 415 via the gap 423. At first, as the second spring 435 is loaded it exerts a tension force downward on the mounting cup 415. The rod 440 engages with a wall of the gap 423 and prevents the mounting cup 415 from rotating. In some embodiments, a different braking mechanism can prevent rotation of the mounting cup 415. For example, an inelastic wire or cord can be coupled to the mounting cup 415 and fixed at the other end such that the second spring 435 rotates the mounting cup 415 until the inelastic cord is taunt. Still, in other embodiments, a rack and pinion or any other mechanism for inhibiting partial or complete rotation (e.g., 360 degrees) of the mounting cup 415 may be used. In other embodiments, a shoulder bolt or a wedge may be used.

Referring still to FIGS. 7 and 8, second spring 435 may be coupled to a first part of the bracket 450, shown as first part 445. The first part 445 may also include a cutout or aperture to let the wire 427 pass through. In some embodiments, the first part 445 includes a second cutout, aperture or hole, shown as aperture 446 to receive a clip end of the bracket 450, shown as tab 447. At an opposing end, the bracket 450 is coupled to the sensor housing 401 by a fastener, shown as bolt 453. The bracket 450 is removed by removing the bolt 453 so the bracket 450 is free at one end and removing the tab 447 from the aperture 446. In some embodiments, the bracket 450 and first part 445 may be made out of an elastic material (e.g., aluminum, steel, plastic, etc.) such that the first part 445 can be pulled off the tab 447 to release the bracket 450. Upon releasing the bracket 450, the first spring 430 is also released and the mounting cup 415 no longer experiences the first force to seat the mounting cup 415 to the pin 405. The bracket 450 may act as backstop to one or more force exerting members (i.e., resilient members) exerting a force on the mounting cup 415.

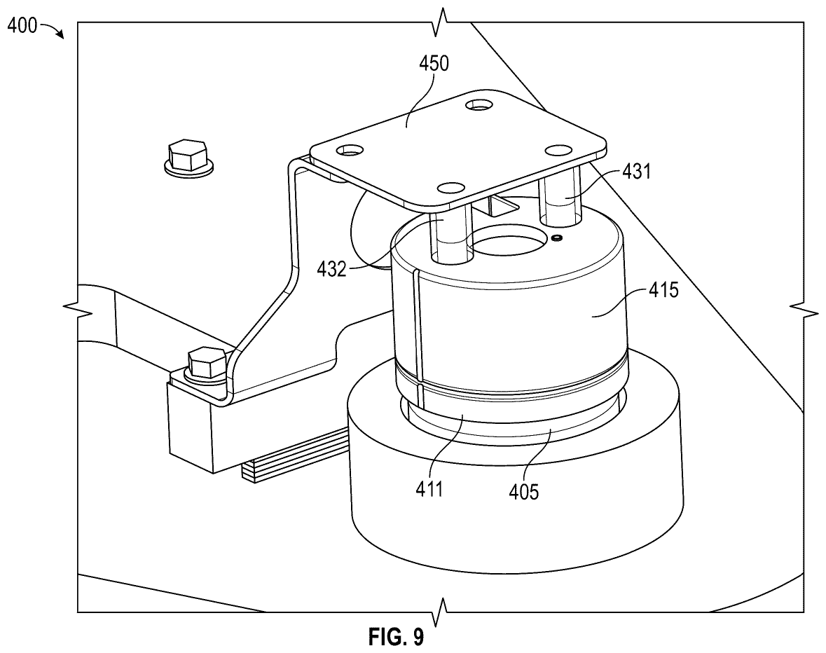

Referring now to FIG. 9, in some embodiments the sensor 400 includes two compression springs 431 and 432 between the bracket 450 and the mounting cup 415. The compression springs 431 and 432 can prevent rotation of the mounting cup 415 and help to ensure the mounting cup 415 stays in contact with the pin 405 as the pin rotates. The compression force also makes sure the airgap between the sensor magnet 410 and the magnetic sensor 425 remains relatively constant. Due to friction between the rotating pin 405 and the mounting cup 415 a small rotational force can be imparted on the mounting cup 415. In addition to providing a compressive force, the springs 431 and 432 can counteract the rotational forces acting on the mounting cup 415 to hold it in a generally stationary position. The springs 431 and 432 have an inherent resistance to buckling and thereby resist the rotational forces acting the mounting cup 415. In such embodiments, the second spring 435 may be excluded, and all rotational resistance provided by the springs 431 and 432.

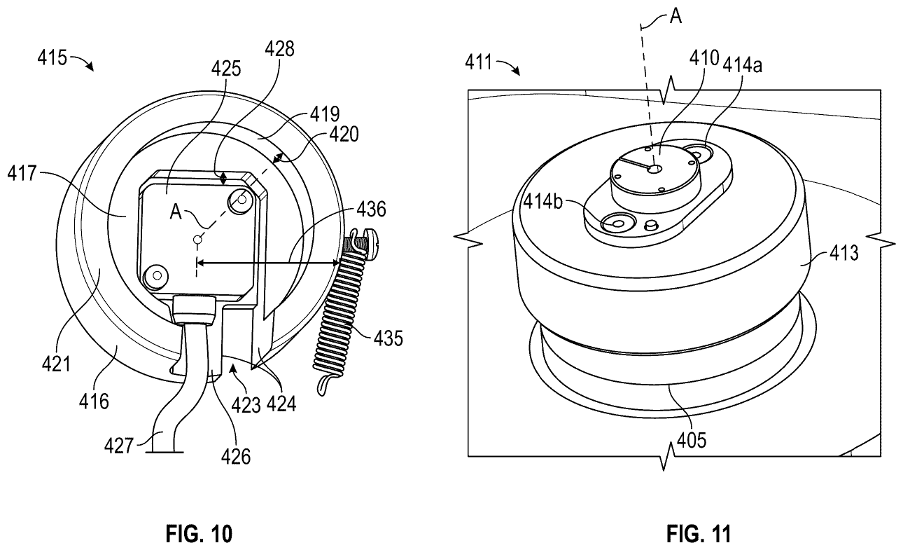

Referring now to FIG. 10, the mounting cup 415 is shown, according to an exemplary embodiment. The mounting cup 415 includes an outer lateral surface shown as exterior 416. The magnetic sensor 425 is coupled to a sensor mounting surface 426. The mounting cup 415 includes a second, intermediate surface, shown as engagement surface 417. The engagement surface 417 is offset along the axis A from the sensor mounting surface 426 a distance 428. Extending around the perimeter of the mounting cup 415 is an outer rim, shown as rim 421. Rim 421 is offset along the axis A from the engagement surface a distance 420. The inner lateral wall of the rim 421 is shown as the horizontal engagement surface 419. The rim 421 includes a gap, cutout, notch, etc., shown as gap 423. The gap 423 allows a wire 427 extending from the magnetic sensor 425 to exit the mounting cup 415. The gap 423 also provides vertical surfaces 424. The vertical surfaces 424 engage with the rod 440 to prevent the mounting cup 415 from rotating greater than the arc length of the gap 423. The second spring 435 is shown coupled to an exterior 416 of the mounting cup a distance 436 from the axis A and a center of the magnetic sensor 425.

Referring now to FIG. 11, the pin 405 is shown, according to an exemplary embodiment. The pin 405 is coupled to the adaptor 411. The adaptor 411 is shaped to correspond to the inner perimeter of the rim 421 of the mounting cup 415, such that the adaptor can be received within the mounting cup 415. The adaptor 411 and the mounting cup 415 can be any pair of corresponding shapes. The adaptor 411 includes a vertical engagement surface, shown as vertical engagement surface 412 and a horizontal engagement surface shown as the outer lateral surface 413. The sensor magnet 410 is coupled to the adaptor 411 at the vertical engagement surface 412 by one or more fasteners, shown as fasteners 414a and 414b. The sensor magnet 410 is positioned to be axially aligned with the axis A of the pin 405. In other embodiments, the sensor magnet 410 is mounted to any one or more surfaces of the adaptor 411, such that the sensor magnet 410 position is maintained at an appropriate distance from the magnetic sensor 425.

Referring now to FIGS. 10 and 11, when the mounting cup 415 receives the adaptor 411 and the sensor magnet 410, the engagement surface 417 of the mounting cup 415 abuts or is adjacent to the vertical engagement surface 412 of the adaptor 411. The engagement surface 417 and the vertical engagement surface 412 are substantially parallel, such that the surfaces prevent angular misalignment between magnetic sensor 425 in the mounting cup 415 and the sensor magnet 410. When the mounting cup 415 receives the adaptor 411 and the sensor magnet 410, the horizontal engagement surface 419 of the sensor mount abuts or is adjacent to the outer lateral surface 413 of the adaptor 411. The horizontal engagement surface 419 and the outer lateral surface 413 are substantially parallel, such that the horizontal engagement surface 419 retains the adaptor 411 axially along the axis A and the magnetic sensor 425 is maintained in a concentric position relative the pin 405.

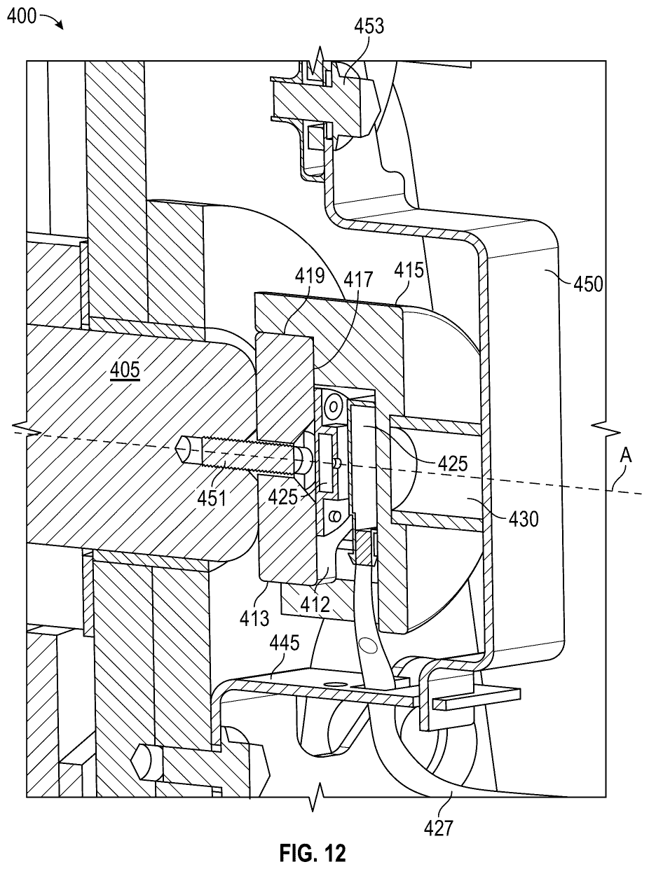

Referring now to FIG. 12, the adaptor 411 is coupled to the pin 405 via a fastener, screw, bolt, etc. shown as screw 451. Screw 451 is threaded into the pin 405 and threaded into the adaptor 411 to retain the adaptor and fixedly couple it to the pin 405.

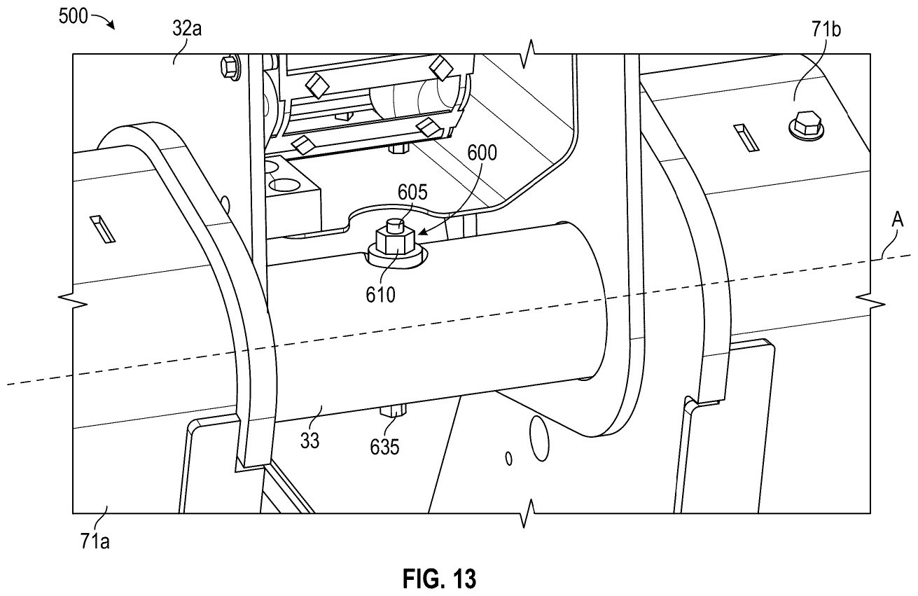

Referring now to FIGS. 13-15, a perspective view of a pin-joint 500 is shown, according to an exemplary embodiment. The pin-joint 500 can correspond to one or more of the pivot points 84a-84c of the lift device 10. The pin-joint 500 includes a fork, shown as fork with a first fork arm and a second fork arm shown as first fork arm 71a and second fork arm 71b. The first fork arm 71a and the second fork arm 71b are spaced apart to form a gap to receive an eye 33 of a rotatable member (e.g., a lift arm), shown as lift arm 32a. The eye 33 is rotatable relative to the first fork arm 71a and the second fork arm 71b.

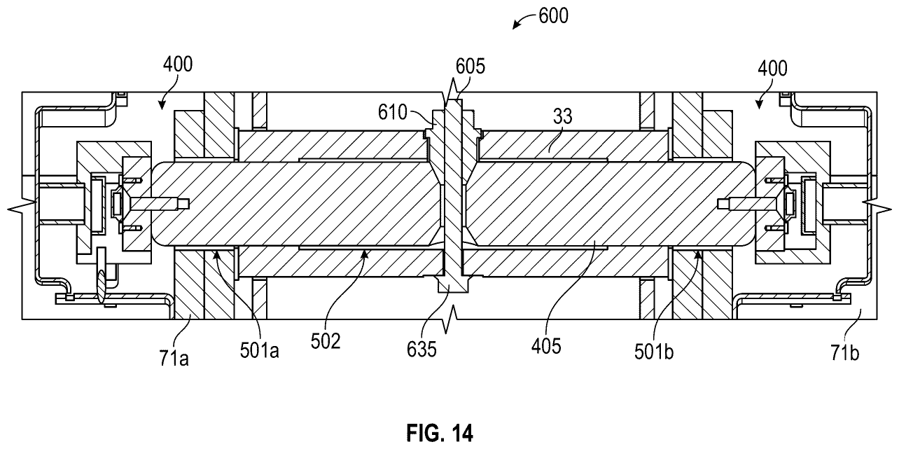

Referring particularly to FIG. 14, the first fork arm 71a, the second fork arm 71b and the eye 33 include concentric apertures 501a, 501b, and 502 to receive the pin 405. The pin 405 extends through the aperture 502 of the eye 33 and through each aperture 501a and 501b into individual sensors 400 at each end of the pin 405. The pin 405 is fixedly coupled to the eye 33 by a bolt, shown as a threaded bolt 605. The threaded bolt 605 fixes the pin 405 to the eye 33 such that rotation of the eye 33 rotates the pin 405.

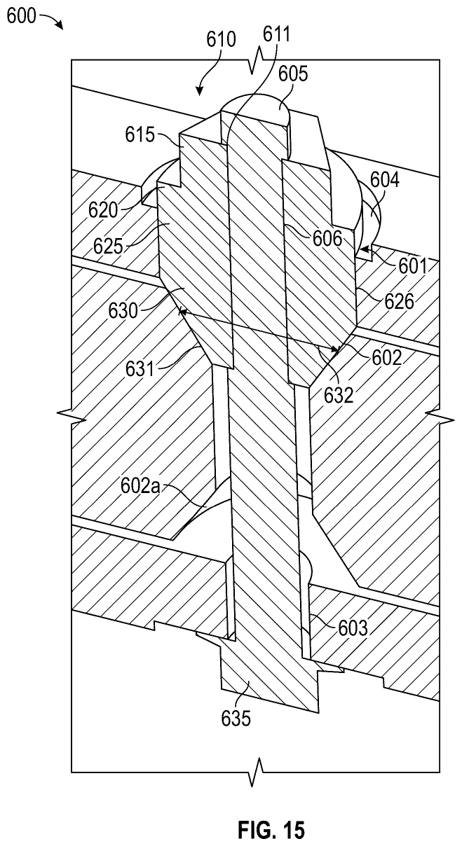

Referring particularly to FIG. 15, the bolt assembly 600 includes a threaded bolt 605. The bolt 605 is retained in a tapered cone, shown as cone 610. The cone 610 includes a flange, rim or stop, shown as flange 620. Extending from the flange 620 away from the pin 405 is a head, shown head 615. The head 615 may be a hex head, however the head 615 may have any number of planar or non-planar surface for driving the cone 610. Extending away from the flange 620 opposite the head 615 is the cone 610 includes a threaded lateral surface, shown as intermediate portion 625 with threads 626. Extending away from the intermediate portion 625 is a tapered end of the cone 610, shown as taper 630. A diameter 632 of the taper 630 decreases as the taper 630 extends away from the intermediate portion 625. In some embodiments, the taper 630 extends entirely around the cone 610. In other embodiments, the taper extends around only a portion of the cone 610.

The bolt 605 passes through a threaded central aperture of the cone 610 shown as aperture 611, which extends through the head 615, the flange 620, the intermediate portion 625, and the taper 630. The bolt 605 also passes through the first threaded aperture 601 of the eye 33, a tapered aperture 602 of the pin 405, and a second aperture 603 of the eye 33. The threads of the bolt 605 engage with internal threads 606 of the central aperture 611 of the cone 610 to secure the bolt 605 with the cone 610. When the cone 610 is inserted in the first threaded aperture 601, external threads 626 of the cone engage with the internal threads of the first threaded aperture 601 until the flange 620 of the cone 610 engages with a rim of the first threaded aperture 601, shown as rim 604, to seat the cone 610.

Still referring to FIG. 15, as the cone 610 is threaded into the eye 33, a tapered surface 631 of the taper 630 of the cone 610 engages with a corresponding taper of tapered aperture 602 of the pin 405. The taper 630 and the corresponding tapered aperture 602 are parallel or substantially parallel and concentric or substantially concentric with a longitudinal axis of the bolt 605. The cone 610 is fixedly coupled to the eye 33. For example, the cone 610 is threaded into the first threaded aperture 601 until the flange 620 and the taper 630 engage the rim 604 and the tapered aperture 602, respectively. In other embodiments, the cone 610 may be welded, glued, or otherwise removably coupled or permanently coupled to the eye 33. An end of the bolt 605 opposing the cone 610 includes a bolt head 635 for driving the bolt 605 through the eye 33, the pin 405 and into the threaded cone 610. The bolt 605 is threaded into the cone 610 and engages with the internal threads 606 to further secure the threaded cone 610. In some embodiments, an additional nut is threaded onto the bolt 605 opposite the bolt head 635 to secure the bolt 605 with the eye 33, the pin 405, and the threaded cone 610. In such embodiments, the internal threads 606 of the cone 610 may be excluded, and the bolt 605 is solely retained with the nut on the bolt end opposing the bolt head 635. In some embodiments, the external threads 626 of the threaded cone 610 are excluded, and the threaded cone 610 is instead retained in place solely by the bolt 605. In other embodiments, the bolt 605 is excluded and the threaded cone 610 is retained in place by the external threads 626 of the threaded cone 610 engaging with the first threaded aperture 601.

Beneficially, the tapered cone 610 reduces the relative motion between the eye 33 and the pin 405. Reducing the relative motion or rotational backlash between the eye 33 and the pin 405 improves the accuracy of rotary sensors such as the sensors 400. In some embodiments, the pin 405 includes an additional tapered aperture shown as tapered aperture 602a, and a second cone 610 is used opposite the first cone 610. In some embodiments, multiple bolt assemblies 600 are used axially along the axis A to secure the eye 33 with the pin 405. While shown as separate components, in some embodiments, the bolt 605 and the cone 610 may be integrated into a single component.

In some embodiments, the tapered cone 610 engages with the eye 33 via the threads 626, without the use of the bolt 605. In such embodiments, the taper 630 of the cone may still engage with a corresponding taper of tapered aperture 602 of the pin 405.

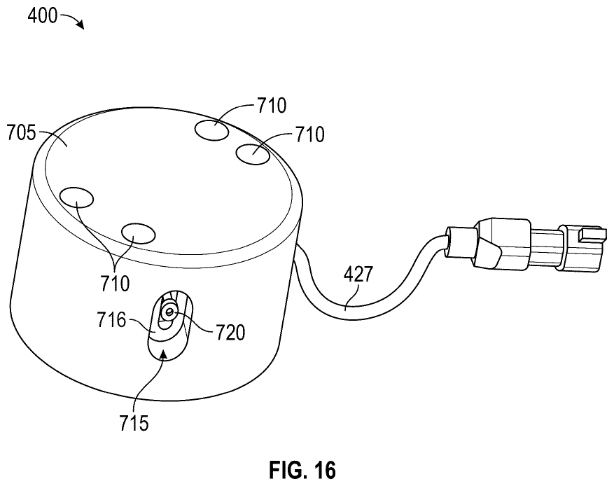

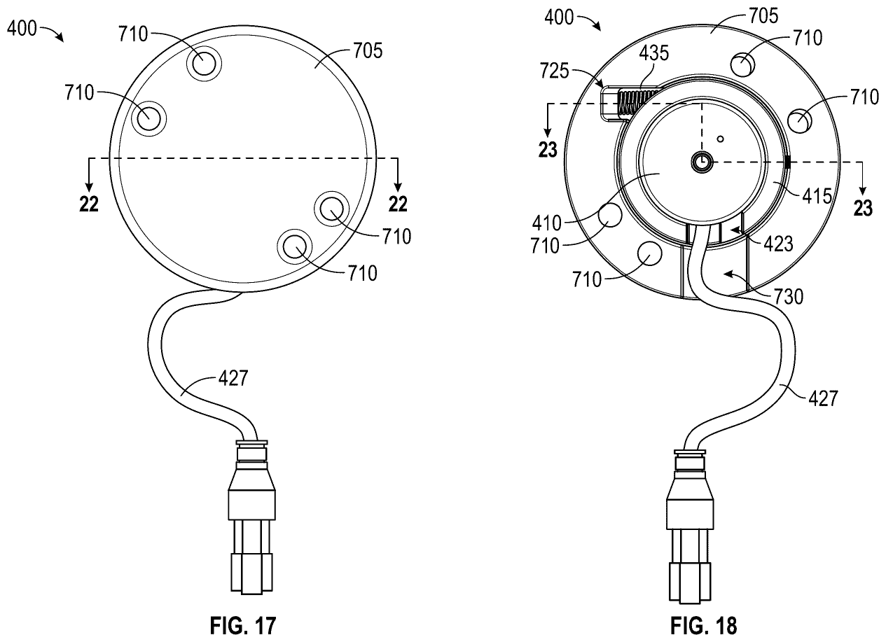

Referring now to FIGS. 16 and 17 the sensor 400 is shown according to another embodiment. The sensor 400 includes an external cup or cover, shown as external cup 705. The external cup 705 partially surrounds the mounting cup 415 as shown in FIG. 18. A bottom of the external cup 705 is open to allow for the external cup 705 to be slid onto the mounting cup 415. The external cup 705 includes a plurality of slots 710. The slots 710 allow for one or more fasteners (e.g., bolts, screws, pins, or other fastening means) to couple the external cup 705 to a lift device, such as at a pivot point 84. In some embodiments, the external cup 705 replaces the bracket 450, and holds the mounting cup 415 in place as well as any force exerting members (i.e., resilient members) acting on the mounting cup 415.

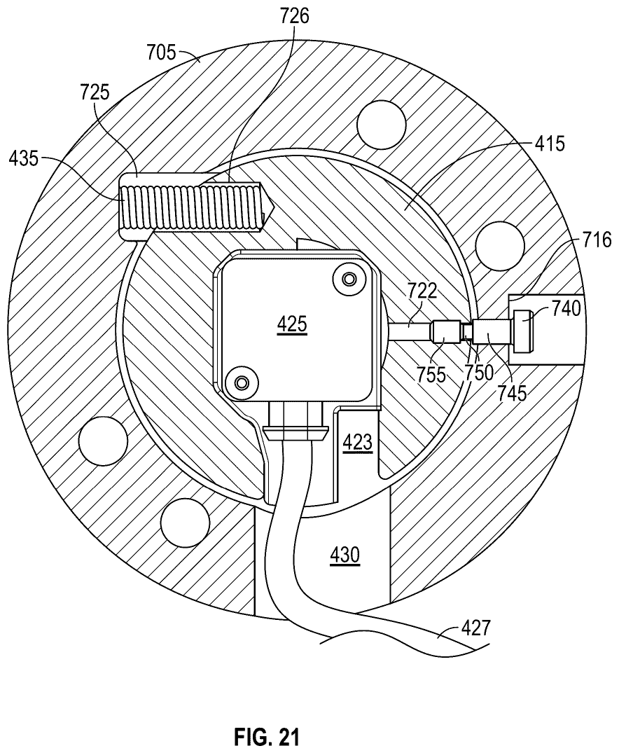

The external cup 705 includes a hole, slot, or aperture, shown as slot 715, extending at least partially along a vertical axis of the external cup 705, from the open bottom end towards the closed top end. Extending from the slot 715 is a shoulder bolt 720, explained in further detail below with reference to FIGS. 20-23. The slot 715 includes a sunken portion forming a ledge 716, that extends only partially into the external cup 705. The ledge 716 surrounds the interior of the slot 715 which extends entirely through the external cup 705. In some embodiments, the slot is angled or jagged. In some embodiments, the slot 715 includes one or more horizontal and/or one or more vertical portions. The external cup 705 also includes an aperture to allow the wire 427 to pass through.

Referring now to FIG. 18, a bottom view of the sensor 400 of FIG. 16 is shown. The external cup 705 is shown surrounding the mounting cup 415. Within the mounting cup 415 is the sensor magnet 410. Behind the sensor magnet 410 is the magnetic sensor 425, for example as shown in FIGS. 7 and 12. The wire 427 extends through a gap 423 in the mounting cup 415 and a gap 730 in the external cup 705.

As shown in FIG. 18, the external cup 705 includes a cavity, shown as spring cavity 725. Spring cavity 725 extends from the inside of the external cup 705 at least partially through the external cup 705. Retained within the spring cavity 725 is the second spring 435. In the sensor 400 shown in FIG. 18, rather than the second spring 435 being coupled to the bracket 450 as shown in FIG. 7, the second spring 435 is coupled to the external cup 705. When the external cup 705 is secured to a pivot point of a lift device (e.g., pivot point 84) the external cup 705 acts as a fixed point from which the second spring 435 may act against. The external cup 705 and the second spring 435 thus act to prevent rotation of the mounting cup 415 relative to the its mounting location and the sensor magnet 410 (though the sensor magnet 410 is free to rotate relative to the mounting cup 415. While only a single spring cavity 725 is shown, in some embodiments there may be multiple spring cavities 725. For example, there may be opposing spring cavities. In some embodiments, the spring cavity 725 may be curved. In some embodiments, the spring cavity 725 may extend entirely through the external cup 705 and the second spring 435 is retained by a fastener coupled to an exterior of the external cup 705.

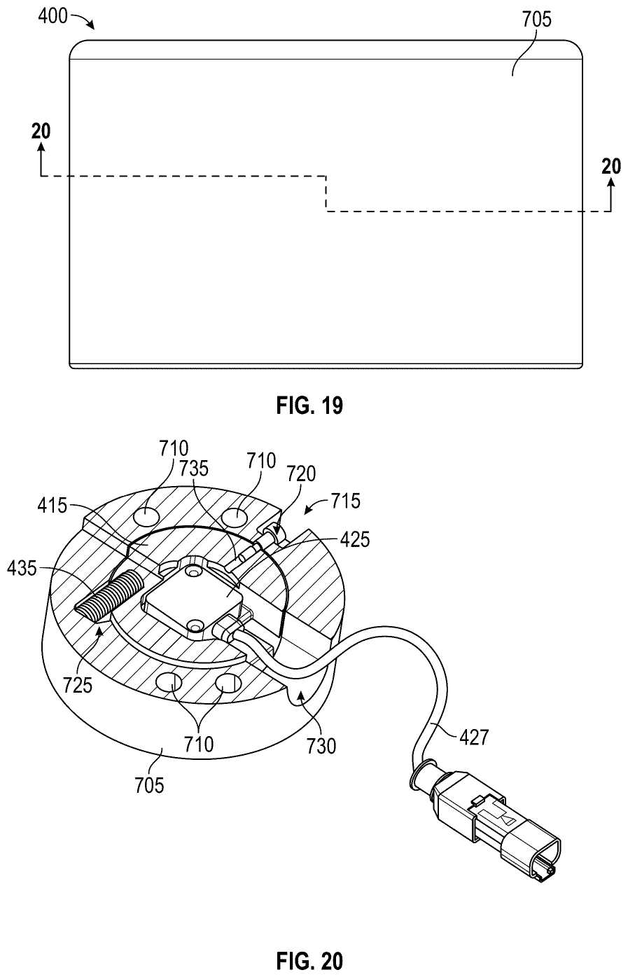

Referring to FIG. 19, a front of the sensor 400 of FIG. 16 is shown, according to an embodiment. FIG. 20 is a section view of the sensor 400 of FIG. 16 at the section line 20 shown in FIG. 19 and FIG. 21 is a top down view of the section view of FIG. 20.

Referring now to FIGS. 20 and 21, section 20 shows the slot 715 of the external cup 705 and the shoulder bolt 720. The shoulder bolt 720 passes through the slot 715 of the external cup 705 and into a slot or aperture, shown as slot 735 of the mounting cup 415. The shoulder bolt 720 includes a head, shown as head 740, adapted to receive one or more tools for installing the shoulder bolt 720. Extending away from the head 740 is an upper shoulder 745. The upper shoulder 745 is separate by a narrow portion shown as connection portion 750 from a lower shoulder 755. The lower shoulder 755 may have a diameter less than a diameter of the upper shoulder 745. The lower shoulder 755 extends at least partially into the slot 735. In some embodiments, the lower shoulder 755 is threaded and is threadably coupled with the mounting cup 415. The shoulder bolt 720 acts to inhibit or limit rotation of the mounting cup 415, and in turn the magnetic sensor 425, relative to the external cup 705, and in turn the lift device. In some embodiments, the shoulder bolt 720 functions similarly to the rod 440 discussed above. As one of the external cup 705 or the mounting cup 415 rotates relative to other of the external cup 705 or the mounting cup 415, the upper shoulder 745 contacts the slot 715 an and prevents any further rotation of the external cup 705 relative to the mounting cup 415. In some embodiments, the second spring 435 is pre-tensioned to cause the shoulder bolt 720 to engage with the slot 715 in a resting or default position. While a diameter of the upper shoulder 745 is shown as substantially equal to a diameter of the slot 715, in some embodiments the diameter of the upper shoulder 745 is less than the diameter of the slot 715 to allow for a predetermined amount of play between the external cup 705 and the mounting cup 415.

Referring still to FIGS. 20 and 21, the second spring 435 is shown to extend at least partially into the mounting cup 415 in second spring cavity 726. In a resting or stable condition, the second spring cavity 726 is shown aligned with the spring cavity 725. If the one of the external cup 705 or the mounting cup 415 were to rotate relative to the other, the spring cavity 725 and the second spring cavity 726 would move apart from each other. As the second spring 435 is coupled to each of the spring cavity 725 and the second spring cavity 726, this movement causes the second spring 435 to stretch and impart a force in the opposite direction of rotation. The second spring 435 may be mechanically fastened, glued, potted, or otherwise couple to the mounting cup 415 in the second spring cavity 726 and the spring cavity 725.

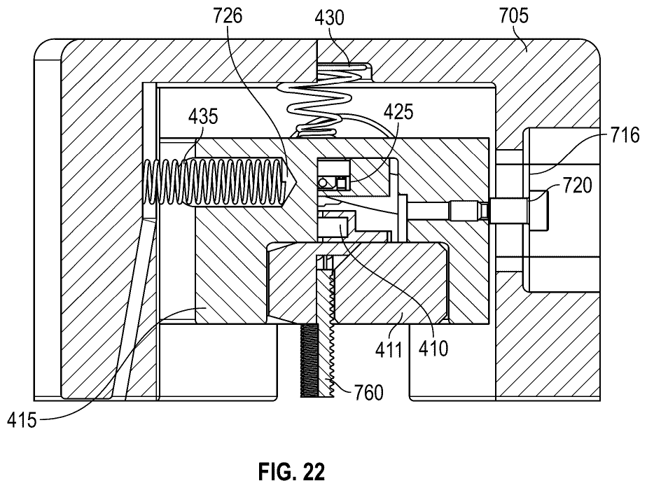

Referring now to FIG. 22, a section view across the section line 22 of FIG. 17 is shown, according to an exemplary embodiment. As discussed above with reference to at least FIGS. 7 and 9, a force exerting member (e.g., a resilient member such as a spring or expanding foam) applies an axial force onto the mounting cup 415 substantially parallel with an axis of rotation of the pivot point the sensor 400 is coupled to. As shown in FIG. 22, the first spring 430 is positioned between the external cup 705 and the mounting cup 415. The first spring 430 is shown as a coil spring, and applies an axial force down towards the open end of the external cup 705.

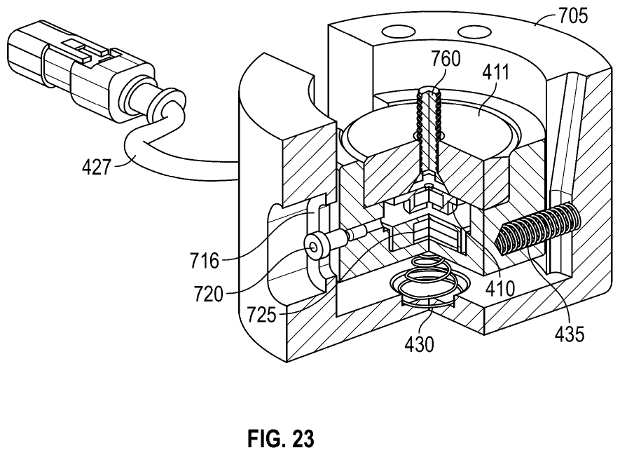

Still referring to FIG. 22, the magnetic sensor 425 is positioned above the sensor magnet 410 which is coupled to the adaptor 411. As discussed above, the adaptor 411 may be fixedly coupled to a pin such as pin 405 such that rotation of the pin 405 causes rotation of adaptor 411 and in turn the sensor magnet 410. A threaded rod 760 is shown extending from the adaptor 411 to couple the adaptor 411 to pin. As further shown in FIG. 22, the head 740 of the shoulder bolt 720 engages the ledge 716 of the slot 715 to capture the external cup 705. FIG. 23 shows a section view across section line 23 of FIG. 18, and similarly shows the shoulder bolt 720 engaged with the ledge 716 of the slot 715.

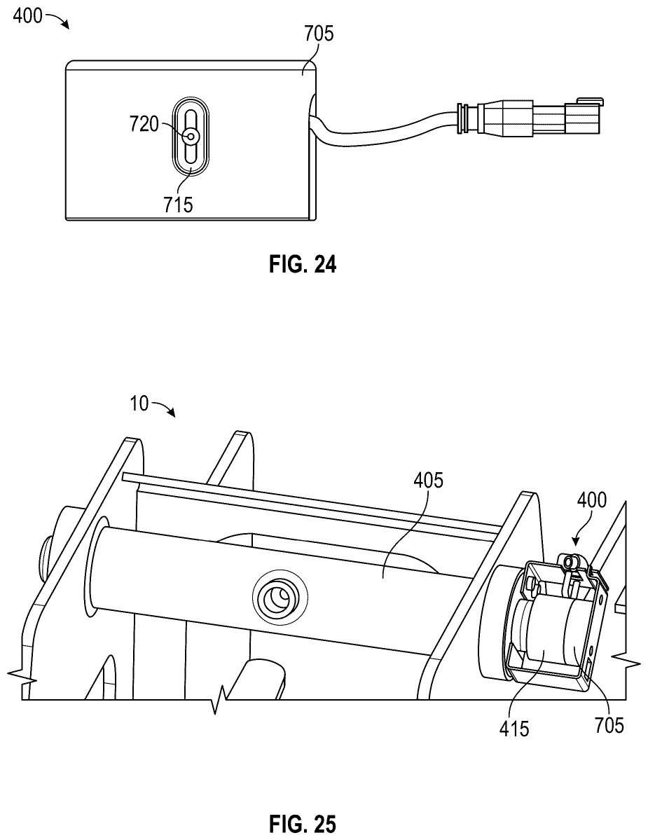

Referring now to FIG. 24, a side view of the sensor 400 of FIG. 16 is shown, according to an exemplary embodiment. The shoulder bolt 720 is shown positioned within the slot 715 of the external cup 705. The slot 715 is shown extending vertically along an axis parallel or substantially parallel with a rotation axis of the sensor magnet 410. This slot 715 allows the mounting cup 415 to move vertically relative to the external cup 705, for example due to the force of the first spring 430, without being impeded by the shoulder bolt 720.

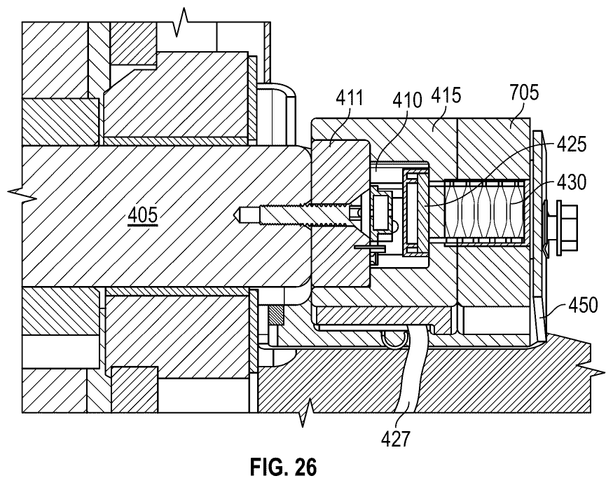

Referring now to FIG. 25, the sensor 400 is shown mounted to a lift device 10, according to an exemplary embodiment. The sensor includes a mounting cup 415 and a external cup 705. The external cup 705 in FIG. 25 is shown as having a diameter substantially the same as the mounting cup 415, such that the mounting cup 415 rests below but not within the external cup 705. As shown in FIG. 26 the external cup 705 contains the first spring 430 in engagement with the mounting cup 415. The external cup 705 is coupled to the bracket 450 to maintain its position.

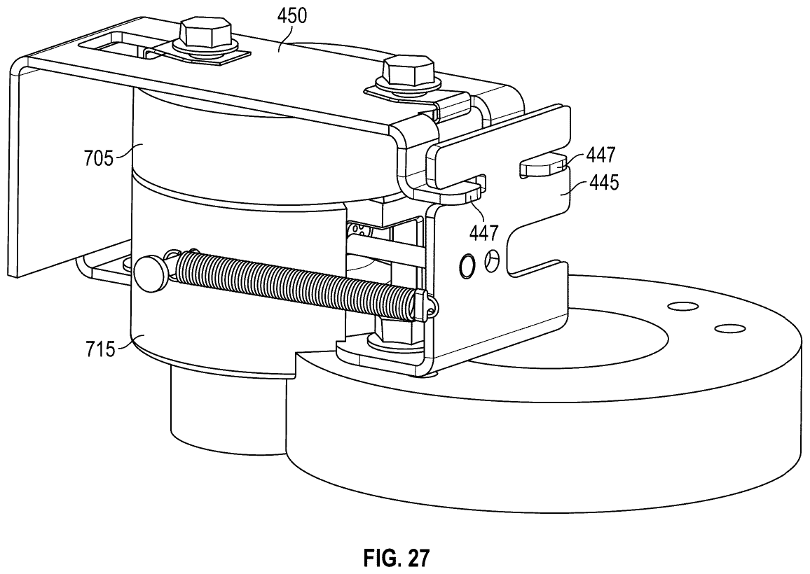

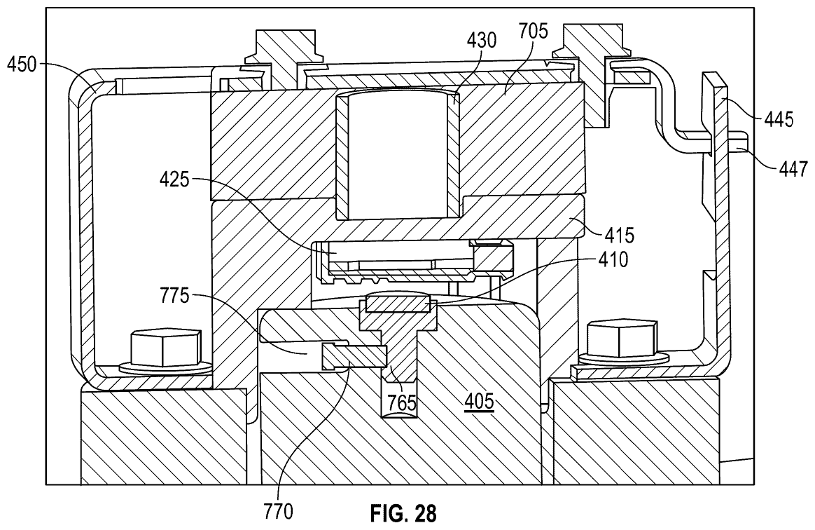

Referring now to FIG. 27, the sensor 400 is shown with the external cup 705, according to another embodiment. The external cup 705 is retained in place by bracket 450. As described above, bracket 450 may be made of metal such as stamped steel or aluminum and provide support to the sensor 400. Referring now to FIG. 28, a section view of the sensor 400 of FIG. 27 is shown. In the sensor 400 of FIG. 27, the sensor magnet 410 is secured to the pin 405 by a set screw 711 in a slot 775 of the pin 405.

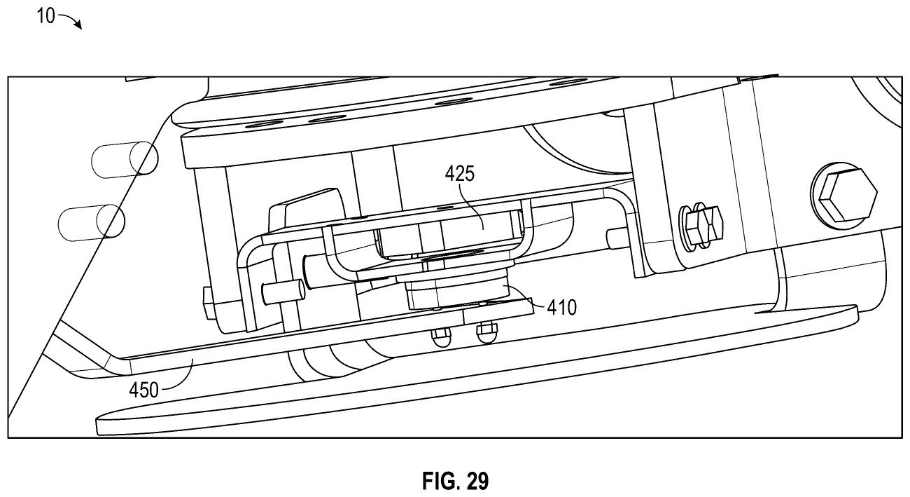

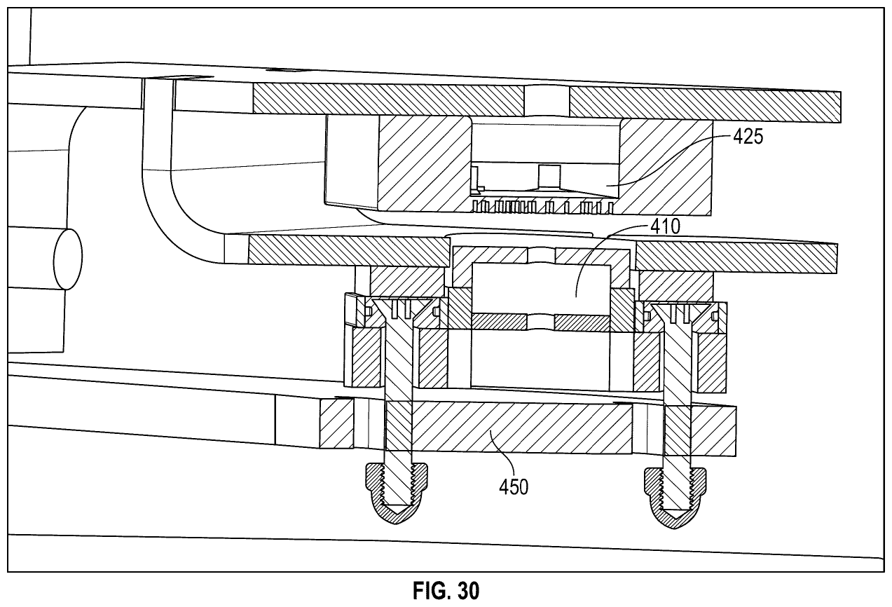

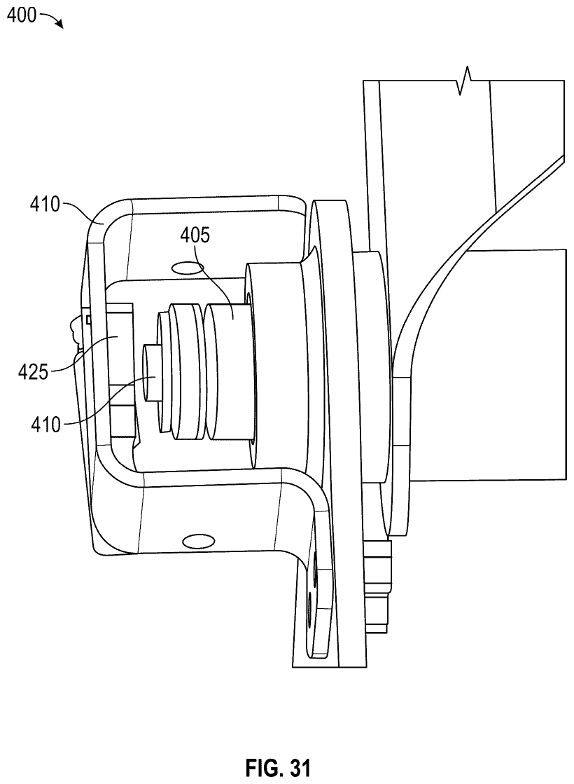

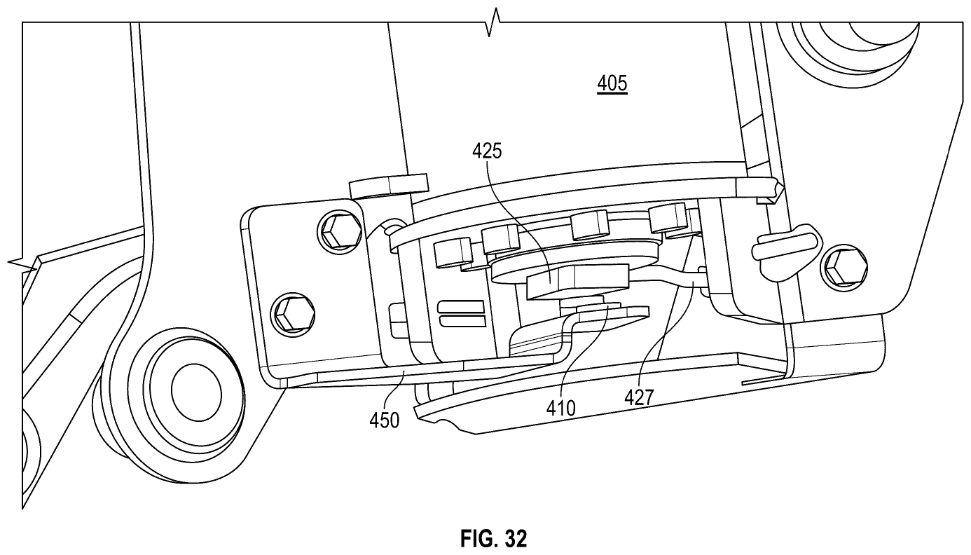

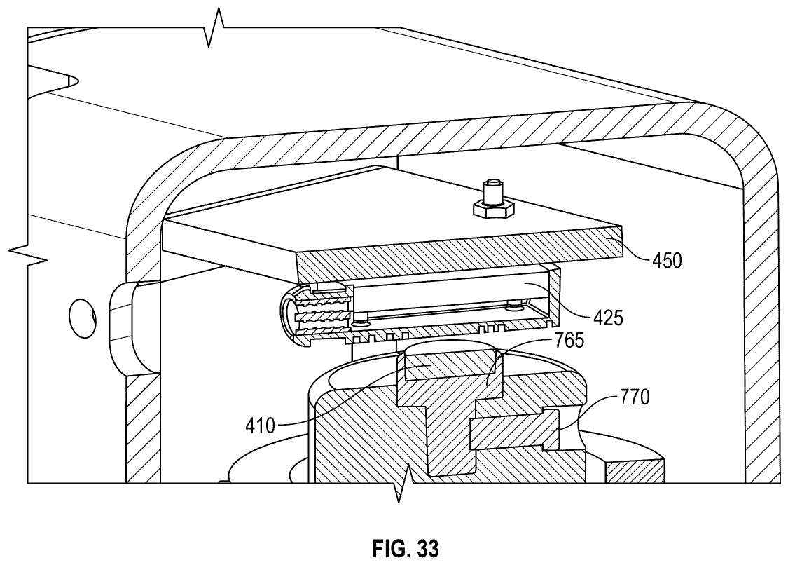

FIGS. 29-33 discloses additional embodiments of the sensor 400 in which an air gap is maintained between the magnetic sensor 425 and the sensor magnet 410 without the use of the mounting cup 415. For example, as shown in FIG. 29, the sensor magnet may be coupled to the bracket 450 and the magnetic sensor 425 coupled to the pin 405 for rotation. FIG. 30 shows a section view of the sensor 400 of FIG. 29. The additional embodiments illustrated in FIGS. 29-33 includes alternative arrangements of bracket 450 to support one of the magnetic sensor 425 and the sensor magnet 410 relative to the other. For example, FIG. 31 shows a sensor 400 with an airgap between the magnetic sensor 425 and the sensor magnet 410 coupled to the pin 405. The magnetic sensor 425 is supported by bracket 450. FIG. 32 shows a sensor 400 with the magnetic sensor 425 coupled to the pin 405 and the sensor magnet 410 supported by the bracket 450. FIG. 33 shows a section view of a sensor 400 with an air gap between the magnetic sensor 425 and the sensor magnet 410. As discussed above, in some embodiments, the magnetic sensor 425 is fixed to the pin 405 and rotates relative to the magnetic sensor 425 which is kept in a fixed orientation, while in other embodiments the sensor magnet 410 is fixed to the pin 405 and rotates relative to the magnetic sensor 425 which is kept in a fixed orientation.

### Configuration of the Exemplary Embodiments

As utilized herein with respect to numerical ranges, the terms “approximately,” “about,” “substantially,” and similar terms generally mean+/−10% of the disclosed values. If values are not disclosed, they mean+/−10% from the null, zero, or absolute value. When the terms “approximately,” “about,” “substantially,” and similar terms are applied to a structural feature (e.g., to describe its shape, size, orientation, direction, etc.), these terms are meant to cover minor variations in structure that may result from, for example, the manufacturing or assembly process and are intended to have a broad meaning in harmony with the common and accepted usage by those of ordinary skill in the art to which the subject matter of this disclosure pertains. Accordingly, these terms should be interpreted as indicating that insubstantial or inconsequential modifications or alterations of the subject matter described and claimed are considered to be within the scope of the disclosure as recited in the appended claims.

It should be noted that the term “exemplary” and variations thereof, as used herein to describe various embodiments, are intended to indicate that such embodiments are possible examples, representations, or illustrations of possible embodiments (and such terms are not intended to connote that such embodiments are necessarily extraordinary or superlative examples).

The term “coupled” and variations thereof, as used herein, means the joining of two members directly or indirectly to one another. Such joining may be stationary (e.g., permanent or fixed) or moveable (e.g., removable or releasable). Such joining may be achieved with the two members coupled directly to each other, with the two members coupled to each other using a separate intervening member and any additional intermediate members coupled with one another, or with the two members coupled to each other using an intervening member that is integrally formed as a single unitary body with one of the two members. If “coupled” or variations thereof are modified by an additional term (e.g., directly coupled), the generic definition of “coupled” provided above is modified by the plain language meaning of the additional term (e.g., “directly coupled” means the joining of two members without any separate intervening member), resulting in a narrower definition than the generic definition of “coupled” provided above. Such coupling may be mechanical, electrical, or fluidic.

References herein to the positions of elements (e.g., “top,” “bottom,” “above,” “below”) are merely used to describe the orientation of various elements in the FIGURES. It should be noted that the orientation of various elements may differ according to other exemplary embodiments, and that such variations are intended to be encompassed by the present disclosure. For example, although the sensor 400 is shown with the sensor magnet 410 coupled to the pin 405 and the magnetic sensor 425 remains stationary relative to the pin 405, it should be noted that the positions can be reversed, with the magnetic sensor 425 coupled to the pin while the sensor magnet 410 remains stationary relative to the pin 405.

The hardware and data processing components used to implement the various processes, operations, illustrative logics, logical blocks, modules and circuits described in connection with the embodiments disclosed herein may be implemented or performed with a general purpose single- or multi-chip processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some embodiments, particular processes and methods may be performed by circuitry that is specific to a given function. The memory (e.g., memory, memory unit, storage device) may include one or more devices (e.g., RAM, ROM, Flash memory, hard disk storage) for storing data and/or computer code for completing or facilitating the various processes, layers and modules described in the present disclosure. The memory may be or include volatile memory or non-volatile memory, and may include database components, object code components, script components, or any other type of information structure for supporting the various activities and information structures described in the present disclosure. According to an exemplary embodiment, the memory is communicably connected to the processor via a processing circuit and includes computer code for executing (e.g., by the processing circuit or the processor) the one or more processes described herein.

The present disclosure contemplates methods, systems and program products on any machine-readable media for accomplishing various operations. The embodiments of the present disclosure may be implemented using existing computer processors, or by a special purpose computer processor for an appropriate system, incorporated for this or another purpose, or by a hardwired system. Embodiments within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. Combinations of the above are also included within the scope of machine-readable media. Machine-executable instructions include, for example, instructions and data which cause a general purpose computer, special purpose computer, or special purpose processing machines to perform a certain function or group of functions.

Although the figures and description may illustrate a specific order of method steps, the order of such steps may differ from what is depicted and described, unless specified differently above. Also, two or more steps may be performed concurrently or with partial concurrence, unless specified differently above. Such variation may depend, for example, on the software and hardware systems chosen and on designer choice. All such variations are within the scope of the disclosure.

It is important to note that the construction and arrangement of the lift device 10 and control system 100 as shown in the various exemplary embodiments is illustrative only. Additionally, any element disclosed in one embodiment may be incorporated or utilized with any other embodiment disclosed herein. For example, the techniques of the platform sensors 202 of the exemplary embodiment shown in at least FIG. 14 may be incorporated in the lift device 10 of the embodiment shown in at least FIG. 5. Although only one example of an element from one embodiment that can be incorporated or utilized in another embodiment has been described above, it should be appreciated that other elements of the various embodiments may be incorporated or utilized with any of the other embodiments disclosed herein.

What is claimed is:

1. A lift device comprising:
a base assembly;
a lift assembly coupled with the base assembly and configured to raise or lower a platform coupled with an end of the lift assembly, the lift assembly comprising;
an arm supported by the base assembly; and
a first pivot comprising a first pivot pin, the arm rotatably relative to the base assembly by the first pivot;
a rotary sensor supported by the base assembly, the rotary sensor configured to monitor a rotation of one of the arm or the first pivot pin about an axis, the rotary sensor comprising:
a mounting cup configured to receive at least a portion of the first pivot pin,
wherein the first pivot pin is rotatable relative to the mounting cup;
an indicator coupled to one of the portion of the first pivot pin or the mounting cup;
an electronic sensor coupled to the other of the portion of the first pivot pin or the mounting cup, the electronic sensor configured to monitor a rotation of the indicator; and
a resilient member configured to exert at least one of an axial force or torsional force on the mounting cup along the axis.

2. The lift device of claim 1, wherein the resilient member is at least one of a spring or a foam.

3. The lift device of claim 1, the rotary sensor further comprising, relative to the mounting cup, a non-rotatable member engaged with the mounting cup and configured to counteract the torsional force.

4. The lift device of claim 3, wherein the non-rotatable member is an external cup fixedly coupled to the lift assembly, wherein the external cup at least partially surrounds the mounting cup.

5. The lift device of claim 4, wherein the external cup comprises a slot extending through the external cup the external cup is fixed to the mounting cup by a shoulder bolt extending through the slot and coupled to the mounting cup.

6. The lift device of claim 5, wherein a head of the shoulder bolt is wider than the slot such that the shoulder bolt captures the external cup relative to the mounting cup.

7. The lift device of claim 5, wherein the slot extends along a first axis, such that the mounting cup is free to move within the slot along the first axis relative to the external cup.

8. The lift device of claim 4, wherein the resilient member is coupled at a first end to the mounting cup and at a second end to the external cup.

9. A rotary sensor for a work machine comprising:
a mounting cup configured to receive at least a portion of a pin configured to rotate relative to the mounting cup about an axis;
an indicator coupled to one of the mounting cup or the pin;
an electronic sensor coupled to the other of the mounting cup or the pin, the electronic sensor configured to monitor a rotation of the indicator;
a resilient member configured to exert at least one of an axial force or torsional force on the mounting cup along the axis; and
a fixed rod extending partially within the mounting cup, wherein the fixed rod prevents the mounting cup from rotating 360 degrees.

10. The rotary sensor of claim 9, wherein the resilient member is a first resilient member configured to exert the axial force or the torsional force, the rotary sensor further comprising a second resilient member configured to exert the other of the axial force or the torsional force.

11. The rotary sensor of claim 9, wherein the mounting cup further comprises a first surface perpendicular to the axis and configured to abut a first surface of an indicator mount perpendicular to the axis to maintain an axial position of the electronic sensor relative to the indicator.

12. The rotary sensor of claim 9, wherein the mounting cup further comprises a second surface parallel to the axis and configured to abut a second surface of an indicator mount parallel to the axis to maintain a radial position of the electronic sensor relative to the indicator.

13. The rotary sensor of claim 9, wherein the resilient member maintains an axial position of the mounting cup relative to the indicator.

14. The rotary sensor of claim 9, wherein the torsional force is substantially tangential to the axis.

15. The rotary sensor of claim 9 wherein the fixed rod is a shoulder bolt positioned within a slot of an external cup at least partially surrounding the mounting cup, and wherein the external cup is fixed relative to the mounting cup.

16. The rotary sensor of claim 15, wherein the shoulder bolt is coupled to the mounting cup.

17. The rotary sensor of claim 9, wherein the mounting cup comprises:
a mounting surface configured to receive the indicator or the electronic sensor;
an engagement surface separated from the mounting surface a distance D1 by a first lateral surface, wherein the engagement surface abuts the pin; and
a bottom surface and separated from the engagement surface a distance D2 by a second lateral surface, wherein the second lateral surface is in contact with an outer lateral surface of the pin.

18. The rotary sensor of claim 17, wherein the distance D1 and D2 are adjusted to set a desired airgap width between the indicator and the electronic sensor.

19. A pin joint for a work machine comprising:
a first member comprising a fork with a first side and a second side, wherein the first side and the second side have concentric fork apertures;
a second member comprising an eye, wherein the eye is concentric with the fork apertures; and
a pin extending through the fork apertures and the eye to rotatably couple to the first member and the second member,
wherein the pin is fixedly coupled to the second member via a bolt passing through the second member and the pin orthogonal to a rotational axis of the pin, wherein the bolt is retained by a cone-shaped bushing, and
wherein the bolt passes through a threaded aperture of the second member, a threaded center of the bushing, the pin, and a second aperture of the second member to secure the pin to the second member.

20. The pin joint of claim 19, the bushing comprising:
a flange comprising an outer lateral surface, wherein the flange is configured to engage with a rim of an aperture of the second member;
a head extending from the flange away from the pin;
a threaded lateral surface extending away from the flange opposite the head and configured to mechanically engage with the aperture; and
a tapered cone extending away from the threaded lateral surface opposite the flange, wherein a diameter of the tapered cone reduces as the tapered cone extends away from the threaded lateral surface,
wherein the tapered cone partially extends into a corresponding tapered aperture of the pin.
